(19) United States
(12) Patent Application Publication
(10) Pub. No.: US 2026/0113957 A1
(43) Pub. Date: Apr. 23, 2026

(54) SEMICONDUCTOR PACKAGE

(71) Applicant: Samsung Electronics Co., Ltd., Suwon-si (KR)

(72) Inventors: Minki Kim, Suwon-si (KR); Raeyoung Kang, Suwon-si (KR); Jingyu Bae, Suwon-si (KR); Enbin Jo, Suwon-si (KR)

(21) Appl. No.: 19/248,808

(22) Filed: Jun. 25, 2025

(30) Foreign Application Priority Data
Oct. 22, 2024 (KR) 10-2024-0145151

(51) Int. Cl. H01L 23/00; H01L 23/31; H01L 25/16; H10B 80/00

(52) U.S. Cl. CPC H10B 80/00; H10W 74/111; H10W 90/00; H10W 72/952; H10W 90/792

(57) ABSTRACT

There is provided a semiconductor package with minimized physical damage and improved reliability in a structure in which a plurality of memory chips are stacked. The semiconductor package includes a base chip, a plurality of memory chips disposed on the base chip, and a sealing material sealing the plurality of memory chips on the base chip, wherein each of the plurality of memory chips is disposed on a center portion of an upper surface of the base chip, the plurality of memory chips include at least one first memory chip at a bottom thereof and at least one second memory chip disposed on the at least one first memory chip, each of the at least one first memory chip has a larger plan view area than each of the at least one second memory chip.

### CROSS-REFERENCE TO RELATED APPLICATION

This application is based on and claims priority under 35 U.S.C. §119 to Korean Patent Application No. 10-2024-0145151, filed on October 22, 2024, in the Korean Intellectual Property Office, the disclosure of which is incorporated by reference herein in its entirety.

### BACKGROUND

The inventive concept relates to a semiconductor package, and particularly, to a semiconductor package including a structure in which semiconductor chips are stacked.

Along with the rapid development of the electronics industry and demands of users, electronic devices have become increasingly miniaturized and more lightweight. In accordance with the miniaturization and weight reduction of electronic devices, semiconductor packages used therein also have been increasingly miniaturized and more lightweight, and in addition, the semiconductor packages require high reliability with high performance and large capacity. To implement miniaturization, weight reduction, high performance, large capacity, and high reliability, semiconductor chips including a through silicon via (TSV) structure and semiconductor packages having a chip-stacked structure in which such semiconductor chips are stacked have been continuously researched and developed.

### SUMMARY

Aspects of the inventive concept provide a semiconductor package with minimized physical damage and improved reliability in a structure in which a plurality of memory chips are stacked.

Issues addressed by the technical idea of the inventive concept are not limited to the issues mentioned above, and other issues could be clearly understood by those of ordinary skill in the art from the description below.

According to an aspect of the inventive concept, there is provided a semiconductor package including a base chip, a plurality of memory chips disposed on the base chip, and a sealing material sealing the plurality of memory chips on the base chip, wherein each of the plurality of memory chips is disposed on a center portion of an upper surface of the base chip, the plurality of memory chips include at least one first memory chip at a bottom thereof and at least one second memory chip disposed on the at least one first memory chip, each of the at least one first memory chip has a larger plan view area than each of the at least one second memory chip, a first side surface of the base chip, a second side surface of the at least one first memory chip, and a third side surface of the at least one second memory chip extend parallel to each other in a first horizontal direction , and in a second horizontal direction perpendicular to the first horizontal direction, a first gap between the first side surface and the third side surface is greater than a second gap between the second side surface and the third side surface.

According to another aspect of the inventive concept, there is provided a semiconductor package including at least one first memory chip and at least one second memory chip disposed on the at least one first memory chip, wherein each of the at least one first memory chip and the at least one second memory chip is stacked through hyper copper bonding (HCB) on a first memory chip or a second memory chip disposed immediately therebelow, each of the at least one first memory chip has a larger plan view area than each of the at least one second memory chip, the at least one second memory chip is disposed at a center portion of an upper surface of the at least one first memory chip, a first side surface of the at least one first memory chip and a second side surface of the at least one second memory chip extend parallel to each other in a first horizontal direction , and the first side surface and the second side surface have a first gap in a second horizontal direction perpendicular to the first horizontal direction.

According to another aspect of the inventive concept, there is provided a semiconductor package including a package substrate, a first semiconductor device on the package substrate, and at least one second semiconductor device on the package substrate and adjacent to the first semiconductor device, wherein each of the at least one second semiconductor device has a package structure including a base chip, a plurality of memory chips disposed on the base chip, and a sealing material sealing the plurality of memory chips on the base chip, the plurality of memory chips include at least one first memory chip at a bottom thereof and at least one second memory chip disposed on the at least one first memory chip, each of the at least one first memory chip has a larger plan view area than each of the at least one second memory chip, a first side surface of the base chip, a second side surface of the at least one first memory chip, and a third side surface of the at least one second memory chip extend parallel to each other in a first horizontal direction , and in a second horizontal direction perpendicular to the first horizontal direction, a first gap between the first side surface and the third side surface is greater than a second gap between the second side surface and the third side surface.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a semiconductor package according to an embodiment;

FIGS. 2A to 2C are conceptual diagrams illustrating the concept of a hybrid copper bonding (HCB) in the semiconductor package of FIG. 1;

FIGS. 3A and 3B are conceptual diagrams illustrating stress during a chip stacking process in a semiconductor package of a comparative example and the semiconductor package of FIG. 1;

FIGS. 4A and 4B are conceptual diagrams illustrating stress during a high temperature test process in a semiconductor package of a comparative example and the semiconductor package of FIG. 1;

FIGS. 5A and 5B are cross-sectional views of semiconductor packages according to embodiments;

FIG. 6 is a cross-sectional view of a semiconductor package according to an embodiment;

FIGS. 7A to 7C are cross-sectional views of semiconductor packages according to embodiments;

FIGS. 8A to 8D are cross-sectional views of semiconductor packages according to embodiments;

FIGS. 9A and 9B are respectively a perspective view and a cross-sectional view of a system package according to an embodiment; and

FIGS. 10A to 10D are cross-sectional views of semiconductor packages according to embodiments.

### DETAILED DESCRIPTION OF THE EMBODIMENTS

Hereinafter, embodiments are described in detail with reference to the accompanying drawings. Like reference numerals in the drawings denote like elements, and thus their repetitive description will be omitted.

Throughout the specification, when a component is described as "including" a particular element or group of elements, it is to be understood that the component is formed of only the element or the group of elements, or the element or group of elements may be combined with additional elements to form the component, unless the context clearly and/or explicitly describes the contrary.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact.

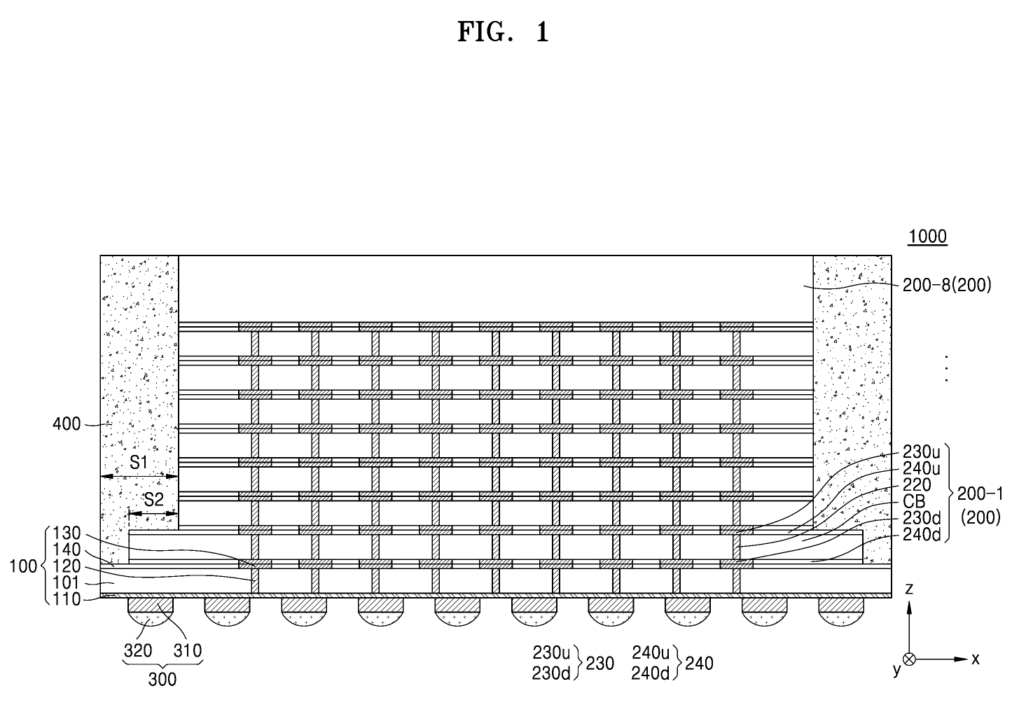

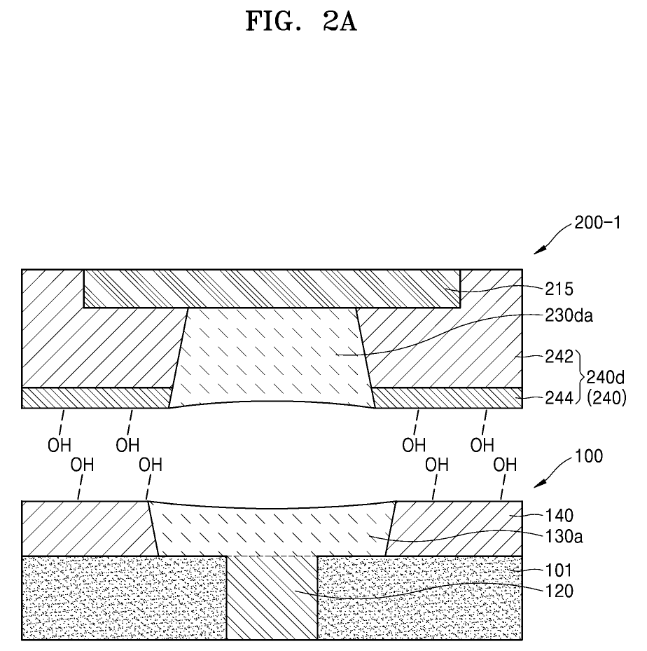

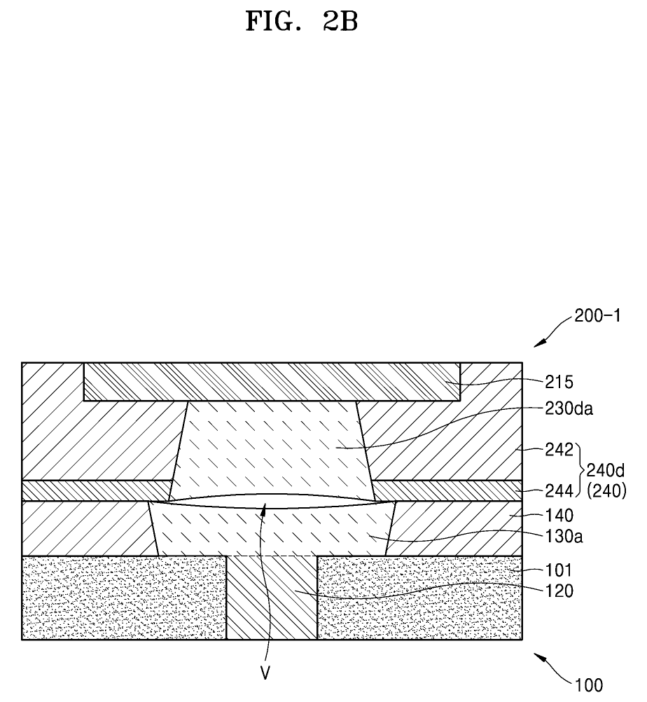

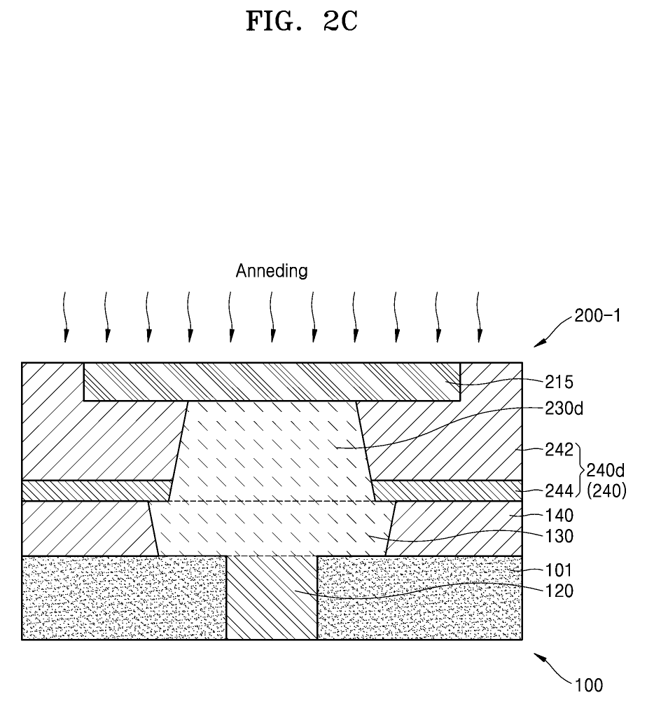

FIG. 1 is a cross-sectional view of a semiconductor package 1000 according to an embodiment, and FIGS. 2A to 2C are conceptual diagrams illustrating the concept of a hybrid copper bonding (HCB) in the semiconductor package 1000 of FIG. 1.

Referring to FIGS. 1 to 2C, the semiconductor package 1000 of the present embodiment may include a base chip 100, memory chips 200, an external connection terminal 300, and a sealing material 400.

The base chip 100 may include a substrate body 101, an active layer 110, a through electrode 120, an upper pad 130, and a protective layer 140. The base chip 100 may have a larger size (e.g., a larger plan view area) than the memory chips 200 disposed thereon, as shown in FIG. 1. However, the size of the base chip 100 is not limited thereto. For example, in some embodiments, the base chip 100 may have substantially the same size as a first memory chip 200-1 that is the lowermost memory chip among the memory chips 200.

The substrate body 101 may include, for example, a semiconductor element, such as silicon (Si) or germanium (Ge). Alternatively, the substrate body 101 may include a compound semiconductor, such as silicon carbide (SiC), gallium arsenide (GaAs), indium arsenide (InAs), or indium phosphide (InP). The substrate body 101 may have a silicon on insulator (SOI) structure. For example, the substrate body 101 may include a buried oxide (BOX) layer. The substrate body 101 may include a conductive area, for example, a structure, such as an impurity-doped well or an impurity-doped source/drain area. The substrate body 101 may have various device isolation structures, such as a shallow trench isolation (STI) structure.

The active layer 110 may include an integrated circuit layer and a multi-wiring layer on the integrated circuit layer. The integrated circuit layer may include various types of devices. For example, the integrated circuit layer may include various active devices and/or passive devices, such as a transistor, logic devices, memory devices, a system large scale integration (LSI) chip, a complementary metal-insulator-semiconductor (CMOS) imaging sensor (CIS), and a micro-electro-mechanical system (MEMS).

The transistor may include, for example, a bipolar junction transistor (BJT) or a field effect transistor (FET), such as a planar FET or a FinFET. The logic devices may include, for example, AND, NAND, OR, NOR, exclusive OR (XOR), exclusive NOR (XNOR), inverter (INV), adder (ADD), delay (DLY), filter (FIL), multiplexer (MXT/MXIT), OR/AND/INV (OAI), AND/OR (AO), AND/OR/INV (AOI), data (D) flip-flop, reset flip-flop, master-slaver flip-flop, latch, counter, and buffer devices. The logic devices may perform various types of signal processing, such as analog signal processing, analog-to-digital (A/D) conversion, and control.

The memory devices may include, for example, flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), resistive random access memory (RRAM), and the like.

The multi-wiring layer may electrically connect at least two devices to each other, electrically connect the at least two devices to the conductive area of the substrate body 101, and/or electrically connect the at least two devices to the external connection terminal 300. In addition, the multi-wiring layer may electrically connect the through electrode 120 to the external connection terminal 300. The multi-wiring layer may include, for example, wirings and a contact and/or a via. In the semiconductor package 1000 of the present embodiment, the active layer 110 may be disposed beneath the substrate body 101 and the through electrode 120. However, in some embodiments, the active layer 110 may be disposed on/above the substrate body 101 and the through electrode 120.

In the semiconductor package 1000 of the present embodiment, the base chip 100 may include a plurality of logic devices in the integrated circuit layer of the active layer 110. The base chip 100 may be disposed beneath the memory chips 200, integrate signals from the memory chips 200 and transmit the integrated signals to the outside, and transmit signals and power from the outside to the memory chips 200. For example, the base chip 100 may be a buffer chip or an interface chip.

In some embodiments, the base chip 100 may include a controller configured to control signal transmission between the memory chips 200 and an external device. When the base chip 100 includes the controller, the base chip 100 may be a logic chip, a control chip, or the like. In some embodiments, the base chip 100 may include a power management integrated circuit (PMIC) configured to manage power or a clock. When the base chip 100 is a buffer chip or the like, the memory chips 200 may be core chips. For example, the memory chips 200 may form a core (e.g., a memory core formed of memory core chips).

In the semiconductor package 1000 of the present embodiment, the base chip 100 is not limited to a buffer chip or a logic chip. For example, the base chip 100 may include a plurality of memory devices in the integrated circuit layer of the active layer 110. Accordingly, the base chip 100 may include a memory chip.

The through electrode 120 may extend from an upper surface of the substrate body 101 to a lower surface thereof by passing through the substrate body 101. In some embodiments, the through electrode 120 may extend into the active layer 110. In the semiconductor package 1000 of the present embodiment, the substrate body 101 may include Si, and accordingly, the through electrode 120 may be a through silicon via (TSV).

The through electrode 120 may have a pillar shape and include a barrier layer on the outer surface thereof and a buried conductive layer therein. The barrier layer may include at least one material selected from among titanium (Ti), titanium nitride (TiN), tantalum (Ta), tantalum nitride (TaN), ruthenium (Ru), cobalt (Co), manganese (Mn), tungsten nitride (WN), nickel (Ni), and nickel boron (NiB). The buried conductive layer may include at least one material selected from among copper (Cu), a Cu alloy, such as copper-tin (CuSn), copper-magnesium (CuMg), copper-nickel (CuNi), copper-zinc (CuZn), copper-palladium (CuPd), copper-gold (CuAu), copper-rhenium (CuRe), or copper-tungsten (CuW), tungsten (W), a W alloy, Ni, Ru, and Co. An insulating layer may be interposed between the through electrode 120 and the substrate body 101 or between the through electrode 120 and the active layer 110. The insulating layer may include, for example, an oxide layer, a nitride layer, a carbide layer, a polymer, or a combination thereof.

The upper pad 130 may be disposed on the upper surface of the substrate body 101 and electrically connected to and/or contact the through electrode 120. The upper pad 130 may include, for example, at least one of aluminum (Al), Cu, Ni, W, platinum (Pt), and gold (Au). In the semiconductor package 1000 of the present embodiment, the upper pad 130 may include Cu. However, the material of the upper pad 130 is not limited to Cu.

The protective layer 140 may be disposed on the upper surface of the substrate body 101. The protective layer 140 may include, for example, an oxide layer, a nitride layer, a carbide layer, a polymer, or a combination thereof. In the semiconductor package 1000 of the present embodiment, the protective layer 140 may have a multi-layer structure. For example, the protective layer 140 may include three insulating layers that are a silicon oxide layer, a silicon nitride layer, and a silicon oxide layer, e.g., sequentially stacked. However, the number of insulating layers included in the protective layer 140 is not limited to 3. In addition, the materials of the insulating layers are not limited to the materials described above.

The upper pad 130 may pass through at least a portion of the protective layer 140, e.g., in a vertical direction. For example, the upper pad 130 may have a structure that completely pass through the protective layer 140 or pass through an upper portion of the protective layer 140, e.g., in the vertical direction, and may be disposed as buried structure in the protective layer 140. The upper pad 130 may be electrically connected to and/or contact the through electrode 120 on an upper surface of the through electrode, e.g., at the same level as the upper surface of the substrate body 101 or at a higher level than the upper surface of the substrate body 101 (e.g., inside the protective layer 140). Although not shown in FIG. 1, a lower protective layer may be disposed on a lower surface of the active layer 110.

The memory chips 200 may be stacked on the base chip 100. In the semiconductor package 1000 of the present embodiment, eight memory chips 200, e.g., first to eighth memory chips 200-1 to 200-8, may be stacked on the base chip 100. However, the number of memory chips 200 stacked on the base chip 100 is not limited to 8. For example, the number of memory chips 200 stacked on the base chip 100 may be 2 to 7, or 9 or more.

As an example, in the semiconductor package 1000 of the present embodiment, the number of memory chips 200 may be 4n (n is a natural number). Accordingly, the semiconductor package 1000 may include a multiple of four memory chips 200, such as four, eight, or twelve memory chips 200. In addition, every four memory chips 200 may be tested and operated with the same stack-identification (ID). For example, when the semiconductor package 1000 includes eight memory chips 200, the first to fourth memory chips 200-1 to 200-4 may have a first stack ID, and the fifth to eighth memory chips 200 may have a second stack-ID. However, the semiconductor package 1000 of the present embodiment is not limited to a multiple of four memory chips 200 and stack-IDs corresponding thereto. For example, the semiconductor package 1000 of the present embodiment may include a multiple of two memory chips 200 and stack-IDs corresponding thereto or a multiple of eight memory chips 200 and stack-IDs corresponding thereto.

Except for the first memory chip 200-1 that is the lowermost memory chip among the memory chips 200, the second to eighth memory chips 200-2 to 200-8 may have the same size. For example, the first memory chip 200-1 may be larger than the second memory chip 200-2 and smaller than the base chip 100. For example, a plan view area of the first memory chip 200-1 may be larger than a plan view area of the second memory chip 200-2. For example, when the first to eighth memory chips 200-1 to 200-8 are disposed at the dead/exact center on the base chip 100 in the X direction, the gap/distance between the side surface of the base chip 100 and the side surface of the second memory chip 200-2 may be a first gap/distance S1, and the gap/distance between the side surface of the first memory chip 200-1 and the side surface of the second memory chip 200-2 in the X direction may be a second gap/distance S2. As shown in FIG. 1, the first gap/distance S1 may be greater than the second gap/distance S2. In addition, the second gap/distance S2 may be greater than 1/2 the first gap/distance S1. For example, in the X direction, the side surface of the first memory chip 200-1 may be closer to the side surface of the base chip 100 than the side surface of the second memory chip 200-2, e.g., in a plan view.

A size relationship among the base chip 100, the first memory chip 200-1, and the second memory chip 200-2 in the Y direction may be the same as or similar to the aforementioned size relationship in the X direction. However, sizes of the first memory chip 200-1 and the second memory chip 200-2 may differ from each other in horizontal directions (the X-direction and the Y-direction), and thicknesses of the first memory chip 200-1 and the second memory chip 200-2 in a vertical direction may be the same as each other. The first memory chip 200-1 and the second memory chip 200-2 may have substantially the same internal structure as each other. For example, integrated circuits formed in the first memory chip 200-1 and the second memory chip 200-2 may be identical to each other.

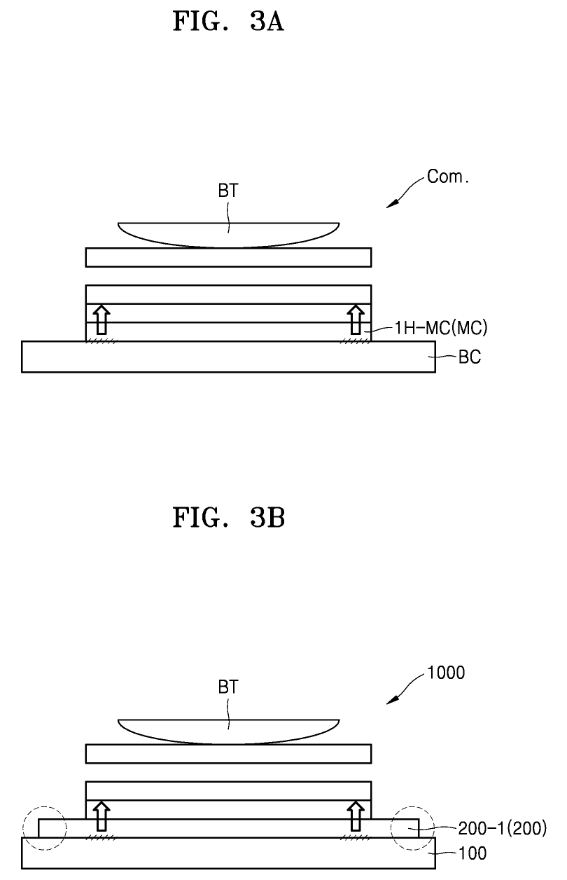

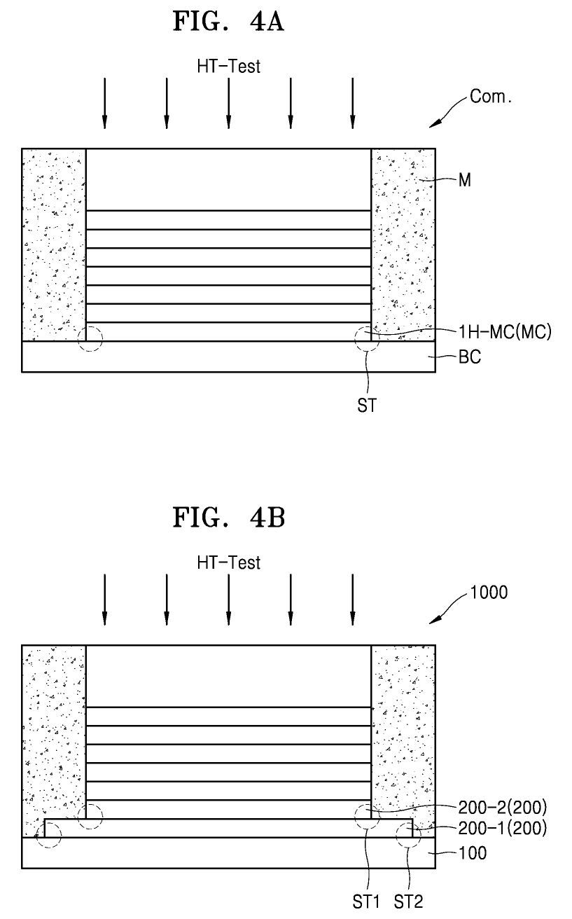

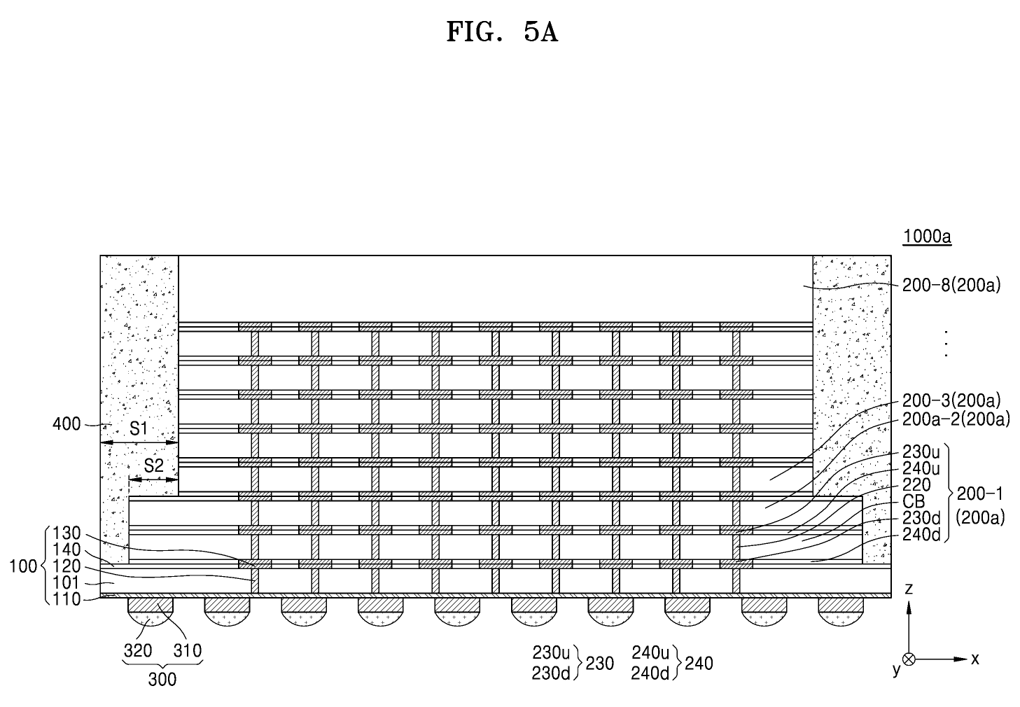

As described below with reference to FIGS. 3a to 4B, as the side surface of the first memory chip 200-1 protrudes from the side surfaces of the other memory chips 200, a delamination phenomenon that an outer portion of the first memory chip 200-1 is delaminated/detached from the base chip 100 may be reduced. Therefore, in some embodiments, in the X direction and the Y direction, the size of the first memory chip 200-1 may be almost the same as the size of the base chip 100.

The second to eighth memory chips 200-2 to 200-8 may have the same horizontal size (e.g., the same plan view area) and internal structure. However, the eighth memory chip 200-8 that is the uppermost memory chip may not include a through electrode. As shown in FIG. 1, the eighth memory chip 200-8 may be thicker than each of the other memory chips 200. In some embodiments, the total height of the semiconductor package 1000 may be adjusted by adjusting the thickness of the eighth memory chip 200-8. Hereinafter, a particular structure of each of the memory chips 200 is described based on the first memory chip 200-1 for convenience. The structure of the first memory chip 200-1 may also be applied to structures of the other memory chips unless contexts indicate otherwise.

The first memory chip 200-1 may include a chip body layer CB, a through electrode 220, a connection pad 230, and one or more protective layers 240. The chip body layer CB may include a substrate body and an active layer. The substrate body of the chip body layer CB is the same as described with respect to the substrate body 101 of the base chip 100.

The active layer of the chip body layer CB may include a plurality of memory devices. For example, the active layer may include volatile memory devices, such as DRAM or SRAM, or non-volatile memory devices, such as PRAM, MRAM, FeRAM, or RRAM. For example, in the semiconductor package 1000 of the present embodiment, the first memory chip 200-1 may include DRAM devices in the active layer. Accordingly, the first memory chip 200-1 may be a DRAM chip. In certain embodiments, the first memory chip 200-1 may be a DRAM chip for high bandwidth memory (HBM). Accordingly, the semiconductor package 1000 of the present embodiment may be an HBM package. However, the semiconductor package 1000 of the present embodiment is not limited to the HBM package.

The through electrode 220 may pass through the substrate body or extend into the active layer by passing through the substrate body. For example, the first memory chip 200-1 may be divided into a cell area and a pad area, and when the through electrode 220 is formed only in the pad area, the through electrode 220 may extend into the active layer by passing through the substrate body. The other description of the through electrode 220 is the same as described with respect to the through electrode 120 of the base chip 100.

The first memory chip 200-1 may include a plurality of connection pads. The connection pads 230 may include a lower pad 230d disposed on a lower surface of the chip body layer CB and an upper pad 230u disposed on an upper surface of the chip body layer CB. In a general semiconductor chip, a chip pad may be disposed on the lower surface of an active layer. Therefore, the lower pad 230d may be or correspond to a chip pad of the first memory chip 200-1.

The lower pad 230d may be electrically connected to and/or contact wirings of a multi-wiring layer of the active layer on the lower surface of the chip body layer CB. In addition, the lower pad 230d may be electrically connected to the through electrode 220 via the wirings of the multi-wiring layer. As a reference, although FIG. 1 shows that the lower pad 230d is directly connected to the through electrode 220, this is for convenience of drawing, and the multi-wiring layer of the active layer may be provided between the through electrode 220 and the lower pad 230d.

The upper pad 230u may be electrically connected to the through electrode 220 on an upper surface of the through electrode 220, e.g., at the same level and the upper surface of the chip body layer CB. The materials and other features of the lower pad 230d and the upper pad 230u are the same as described with respect to the upper pad 130 of the base chip 100.

The protective layers 240 may include a lower protective layer 240d disposed on the lower surface of the chip body layer CB and an upper protective layer 240u disposed on the upper surface of the chip body layer CB. The protective layers 240 may include, for example, an oxide layer, a nitride layer, a carbide layer, a polymer, or a combination thereof. The upper protective layer 240u is the same as described with respect to the protective layer 140 of the base chip 100.

In the semiconductor package 1000 of the present embodiment, the lower protective layer 240d may have a multi-layer structure. For example, the lower protective layer 240d may include three insulating layers that are a tetra-ethyl ortho-silicate (TEOS) oxide layer, a silicon nitride layer, and a TEOS oxide layer, e.g., stacked sequentially. In some embodiments, the lower protective layer 240d may further include an insulating layer of a silicon carbonitride layer as the lowermost layer thereof. However, the number of layers included in the lower protective layer 240d is not limited to 3 or 4. In addition, the materials of the insulating layers are not limited to the materials described above.

The upper pad 230u may pass through at least a portion of the upper protective layer 240u, e.g., in a vertical direction. For example, the upper pad 230u may have a structure that completely passes through the upper protective layer 240u in the vertical direction or passes through an upper portion of the upper protective layer 240u in the vertical direction, and may be disposed as a structure buried in the upper protective layer 240u. For example, the upper protective layer 240u may cover a portion of a top surface of the upper pad 230u. The upper pad 230u may be electrically connected to the through electrode 220 on an upper surface of the through electrode 220, e.g., at the same level as the upper surface of the chip body layer CB, or at a higher level than the upper surface of the chip body layer CB (e.g., inside the upper protective layer 240u).

The lower pad 230d may pass through at least a portion of the lower protective layer 240d, e.g., in the vertical direction. For example, a thick pad metal layer may be disposed inside the lower protective layer 240d, and the lower pad 230d may be electrically connected to and/or contact the pad metal layer by passing through a portion of the lower protective layer 240d, e.g., in the vertical direction. The pad metal layer may be electrically connected to and/or contact the wirings of the multi-wiring layer of the active layer. The pad metal layer may include, for example, Al. Therefore, the lower pad 230d may be electrically connected to the wirings of the multi-wiring layer via the pad metal layer and also electrically connected to the through electrode 220 via the wirings of the multi-wiring layer.

In the semiconductor package 1000 of the present embodiment, the memory chips 200 may be stacked on the base chip 100 or an immediately lower memory chip 200 through HCB. Alternatively, the memory chips 200 may be stacked on the base chip 100 or an immediately lower memory chip 200 through thermal compression bonding (TCB). Herein, HCB may indicate a combination of pad-to-pad bonding and insulator-to-insulator bonding. Because a pad is usually formed of Cu, the pad-to-pad bonding may be Cu-to-Cu bonding.

As described above, the upper pad 130 and the protective layer 140 may be disposed on the upper surface of the base chip 100. In addition, the connection pads 230 and the protective layers 240 may be disposed on the lower surface and the upper surface of each of the memory chips 200. The upper pad 130 of the base chip 100 may pass through at least a portion of the protective layer 140, and the connection pad 230 of each of the memory chips 200 may pass through at least a portion of the protective layer 240. Each of the protective layers 140 and 240 may include, for example, an insulating layer, such as a silicon oxide layer or a silicon nitride layer.

The upper pad 130 of the base chip 100 may be bonded to the lower pad 230d of the first memory chip 200-1, and the protective layer 140 of the base chip 100 may be bonded to the lower protective layer 240d of the first memory chip 200-1, thereby forming HCB between the base chip 100 and the first memory chip 200-1. In addition, between two adjacent memory chips 200 among the memory chips 200, the upper pad 230u and the upper protective layer 240u on the upper surface of a lower memory chip 200 may be bonded to the lower pad 230d and the lower protective layer 240d on the lower surface of an upper memory chip 200, thereby forming HCB.

An HCB process is described in more detail with reference to FIGS. 2A to 2C. FIGS. 2A to 2C are enlarged views of the upper pad 130 of the base chip 100 and the lower pad 230d of the first memory chip 200-1.

Referring to FIG. 2A, an initial upper pad 130a of the base chip 100 may be buried in the protective layer 140 and electrically connected to and/or contact the through electrode 120 at a lower portion thereof. For example, a top surface of the initial upper pad 130a may be at the same level as or at a lower level than a top surface of the protective layer 140. In addition, an initial lower pad 230da of the first memory chip 200-1 may be buried in the lower protective layer 240d and electrically connected to and/or contact a pad metal layer 215 in the lower protective layer 240d. For example, the bottom surface of the initial lower pad 230da shown in FIG. 2A may be at the same level as or at a higher level than a bottom surface of the lower protective layer 240d. For example, the protective layer 140 of the base chip 100 may include a silicon oxide layer, the lower protective layer 240d of the first memory chip 200-1 may include a first insulating layer 242 formed of a silicon oxide layer and a second insulating layer 244 formed of a silicon carbonitride layer. The initial upper pad 130a and the initial lower pad 230da may include, for example, Cu, and each may have a dishing structure of which a center portion is recessed inward, as shown in FIG. 2A. Before bonding of the base chip 100 and the first memory chip 200-1, OH dangling bonds may be formed on the protective layer 140 and the second insulating layer 244 through plasma processing and ultrapure water cleaning processing.

Referring to FIG. 2B, the first memory chip 200-1 is bonded to the base chip 100 at the room temperature such that the initial lower pad 230da is aligned with (e.g., vertically overlap) the initial upper pad 130a. Because the initial upper pad 130a and the initial lower pad 230da have a recessed dishing structure, a void V may exist between the initial upper pad 130a and the initial lower pad 230da at an initial time of bonding.

At the initial time of the bonding, the OH dangling bonds of the protective layer 140 of the base chip 100 and the second insulating layer 244 of the first memory chip 200-1 may form hydrogen bonding (H-D). H-D may have a relatively low bonding force. Accordingly, H-D may have a bonding force to maintain the first memory chip 200-1 on the base chip 100.

Referring to FIG. 2C, thereafter, the initial upper pad 130a and the initial lower pad 230da may expand by applying heat thereto through annealing, such that the void V (see FIG. 2B) disappears and a bonding structure of the upper pad 130 and the lower pad 230d is formed. This process may be a metal expansion process, and when a material is Cu (e.g., in case the upper pad 130 and the lower pad 230d are formed of copper), this process may be a Cu expansion process. In addition, when the bonding structure is formed, compression stress may be applied between the upper pad 130 and the lower pad 230d. Accordingly, the bonding process of the upper pad 130 and the lower pad 230d may be a process of bonding by self-compression, and when a material is Cu (e.g., when the upper pad 130 and the lower pad 230d are formed of copper), the bonding process may be a process of Cu-Cu bonding by self-compression.

When the bonding process between the upper pad 130 and the lower pad 230d is further progressed, metal diffusion (MD) that metal grains move and are mixed with each other may occur between the upper pad 130 and the lower pad 230d. The upper pad 130 may be integrated with the lower pad 230d through MD. If a material is CU, MD may be Cu diffusion or Cu MD.

H-D between the protective layer 140 and the second insulating layer 244 may change to oxide bonding (O-D) through annealing. For example, this is simply represented by a chemical formula -OH + -OH --> O + H₂O through annealing. As an example, the process temperature of annealing may be 150 ℃ or higher. However, the process temperature of annealing is not limited to the numerical value range. O-D may have a higher bonding force than H-D. Accordingly, the first memory chip 200-1 may be firmly bonded onto the base chip 100 with a high bonding force.

In addition, each of the other memory chips 200 on the first memory chip 200-1 may be bonded to an immediately lower memory chip 200 by HCB through the same process as the process described above. For example, in two adjacent memory chips 200, the upper pad 230u and the upper protective layer 240u on the upper surface of a lower memory chip 200 may be bonded to the lower pad 230d and the lower protective layer 240d on the lower surface of an upper memory chip 200 by HCB through the same process as the process described with respect to FIGS. 2A to 2C above.

The external connection terminal 300 may be disposed on the lower surface of the base chip 100. The external connection terminal 300 may be electrically connected to and/or contact the wirings of the multi-wiring layer of the active layer 110. In addition, the external connection terminal 300 may be electrically connected to the through electrode 120 via the wirings of the multi-wiring layer. Although not shown in FIG. 1, a chip pad may be disposed on the lower surface of the base chip 100, and the external connection terminal 300 may be disposed on the chip pad.

The external connection terminal 300 may include a pillar 310 and a bump 320. The pillar 310 may have a cylindrical shape and include, for example, Ni, Cu, palladium (Pd), Pt, Au, or a combination thereof. In some embodiments, the pillar 310 may function as the chip pad of the base chip 100 and include Cu. Accordingly, the pillar 310 may be a bump pad, a Cu pad, a Cu pillar, or the like. When the pillar 310 functions as a chip pad, a separate chip pad may not be formed on the lower surface of the base chip 100.

The bump 320 may be disposed on the pillar 310 and have a semi-spherical shape. The bump 320 may include, for example, solder. The solder may include tin (Sn), indium (In), bismuth (Bi), antimony (Sb), Cu, silver (Ag), zinc (Zn), and/or an alloy thereof. For example, the solder may include Sn, Sn-Ag, Sn-Au, Sn-Cu, Sn-Bi, Sn-Zn, Sn-Ag-Cu, Sn-Ag-Bi, Sn-Ag-Zn, Sn-Cu-Bi, Sn-Cu-Zn, Sn-Bi-Zn, or the like. In some embodiments, the bump 320 may be a solder, a solder bump, or the like. An intermediate layer may be formed in a contact interface between the pillar 310 and the bump 320. The intermediate layer may include an inter-metallic compound (IMC) formed when metal materials included in the pillar 310 and the bump 320 react at a relatively high temperature.

The sealing material 400 may surround/contact the side surfaces of the memory chips 200 on the base chip 100. As shown in FIG. 1, the sealing material 400 may not cover/contact the upper surface of the uppermost memory chip, e.g., the eighth memory chip 200-8. Accordingly, the upper surface of the eighth memory chip 200-8 may be exposed from the sealing material 400. However, in some embodiments, the sealing material 400 may cover/contact the upper surface of the uppermost memory chip, e.g., the eighth memory chip 200-8. The sealing material 400 may include, for example, an epoxy mold compound (EMC). However, the material of the sealing material 400 is not limited to the EMC.

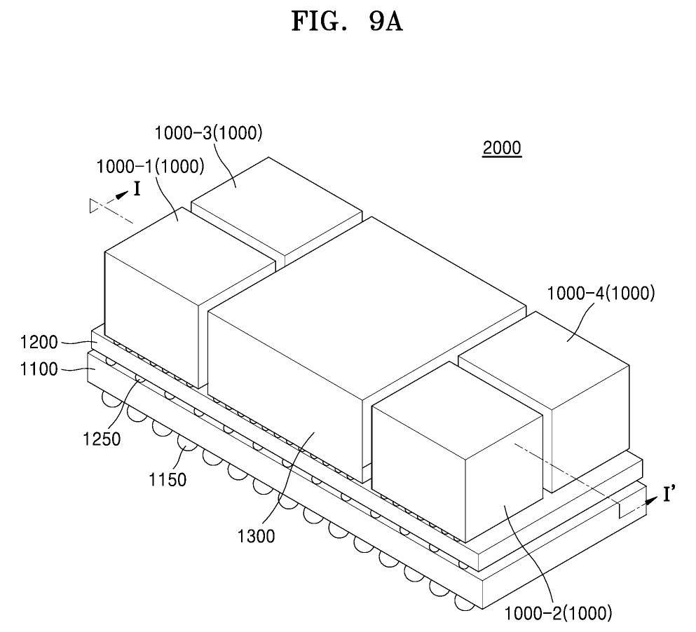

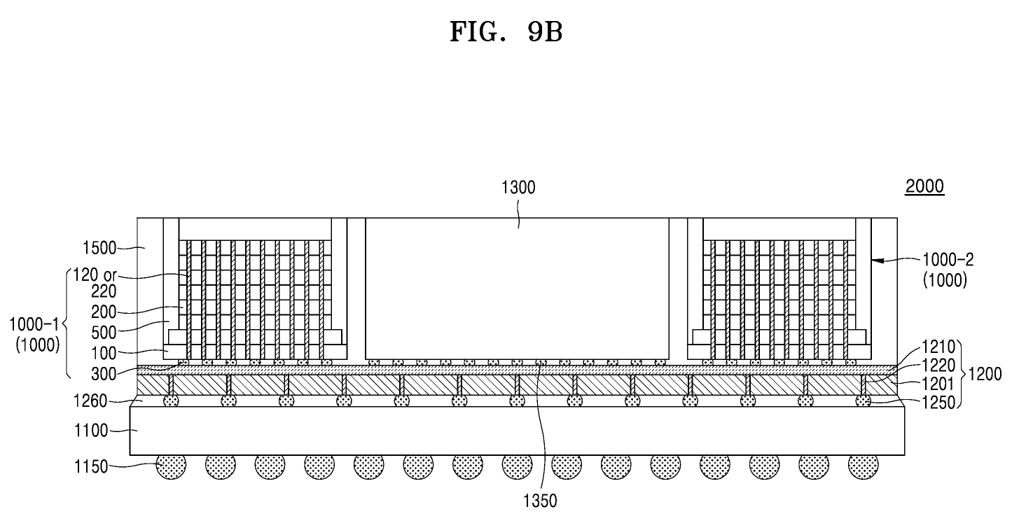

In the semiconductor package 1000 of the present embodiment, the first memory chip 200-1 may have a larger size (e.g., a larger plan view area) than the other memory chips 200 and be disposed on and bonded to the upper surface of the base chip 100, thereby effectively suppressing a delamination phenomenon at a corner and/or an edge of each of the memory chips 200, in particular, the first memory chip 200-1. In addition, by suppressing the delamination phenomenon at the corner and/or the edge of the first memory chip 200-1, physical damage, such as the occurrence of cracks, in the sealing material 400 surrounding the memory chips 200 may be prevented. As a result, the semiconductor package 1000 of the present embodiment may have minimized physical damage, thereby implementing a semiconductor package with improved reliability and a system package 2000 (see FIG. 9A) or a product including the semiconductor package.

FIGS. 3A and 3B are conceptual diagrams illustrating stress during a chip stacking process in a semiconductor package Com. of a comparative example and the semiconductor package 1000 of FIG. 1.

Referring to FIG. 3A, for the semiconductor package Com. of the comparative example, in a process of stacking memory chips MC on a base chip BC, HCB may be performed on each of the memory chips MC. In addition, as shown in FIG. 3A, a bonding tool BT of which a center portion protrudes downward may be used to apply pressure downward. Therefore, tensile stress may occur in an arrow direction shown in FIG. 3A at corner and/or edge portions (a hatched portion) of each of the memory chips MC, in particular, a first memory chip 1H-MC that is the lowermost memory chip among the memory chips MC. For example, upward forces may be applied on edge portions and corner portions of the first memory chip 1H-MC as a reaction to the downward pressure applied by the bonding tool BT. As a result, a delamination phenomenon that the corner and/or edge portions of the first memory chip 1H-MC are/is separated from the base chip BC may be caused. Herein, the corner portions may indicate vertex portions of the lower surface of each of the memory chips MC, and the edge portions may indicate side portions of the lower surface of each of the memory chips MC. A gap between chips due to a delamination phenomenon may cause cracks in a sealing material, an under-fill, and the like surrounding the memory chips MC by influencing the sealing material, the under-fill, and the like in the future or in a later time, thereby decreasing the reliability of a semiconductor package and a system package or product including the semiconductor package.

As an example, in a process of stacking the memory chips MC on the base chip BC, the base chip BC may be in a wafer state. In addition, the base chip BC in the wafer state may adhere to and be fixed to a support wafer (not shown) through an adhesive layer. FIG. 3A shows only a portion corresponding to one base chip BC for convenience.

Referring to FIG. 3B, even in the semiconductor package 1000 of the present embodiment, in a process of stacking the memory chips 200 on the base chip 100, HCB may be performed on each of the memory chips 200. In addition, as shown in FIG. 3B, the bonding tool BT of which a center portion protrudes downward may be used to apply pressure downward. However, because the first memory chip 200-1 has a larger size (e.g., a larger plan view area) than each of the other memory chips 200 thereon, tensile stress may occur in an arrow direction at an outer portion (a hatched portion) of the first memory chip 200-1, corresponding to a corner and/or edge portion of each of the other memory chips 200. As a result, tensile stress may not occur or may be minimized at a corner and/or edge portion (a dotted circle portion) of the first memory chip 200-1. In addition, as the side surface of the first memory chip 200-1 protrudes outward from the side surfaces of the other memory chips 200, a portion where tensile stress occurs may be farther from the corner and/or edge portion of the first memory chip 200-1, thereby further lessening a delamination phenomenon at the corner and/or edge portion of the first memory chip 200-1. For example, upward forces may be applied at inner portions of the first memory chip 200-1 rather than an edge portion or a corner portion of the first memory chip 200-1 as a reaction to the downward pressure applied by the bonding tool BT. As a result, in the semiconductor package 1000 of the present embodiment, a delamination phenomenon that the corner and/or edge portion of the first memory chip 200-1 is separated from the base chip 100 may be prevented, and accordingly, the reliability of the semiconductor package 1000 and a system package or product including the semiconductor package 1000 may be significantly improved.

FIGS. 4A and 4B are conceptual diagrams illustrating stress during a high temperature test process in the semiconductor package Com. of the comparative example and the semiconductor package 1000 of FIG. 1.

Referring to FIGS. 4A and 4B, in general, when a semiconductor package is completed, a high temperature test (HT-Test) may be performed as a reliability test. For example, the process temperature of the HT-Test may be 150 ℃ or higher. For the semiconductor package Com. of the comparative example, in the HT-Test, stress ST may intensively occur at a corner and/or edge portion (a dotted circle portion) of the memory chips MC, in particular, the first memory chip 1H-MC. The stress ST may be caused by the thermal expansion rate differences among the base chip BC, the first memory chip 1H-MC, and a sealing material M. Because the base chip BC and the first memory chip 1H-MC have somewhat similar thermal expansion rates, the stress ST may be largely caused by the thermal expansion rate difference between an exposed portion of the base chip BC and the sealing material M.

However, for the semiconductor package 1000 of the present embodiment, in the HT-Test, because the first memory chip 200-1 is larger than the other memory chips 200, stress caused by the thermal expansion rate difference between the sealing material 400 and an exposed portion of the first memory chip 200-1 and the thermal expansion rate difference between the sealing material 400 and an exposed portion of the base chip 100 may occur. Particularly, in the HT-Test, first stress ST1 may occur at a corner and/or edge portion (a dotted circle portion) of the second memory chip 200-2, and second stress ST2 may occur at a corner and/or edge portion (a dotted circle portion) of the first memory chip 200-1. Therefore, for the semiconductor package 1000 of the present embodiment, in the HT-Test, stress may be dispersed to two points or wider region than the semiconductor package Com. of the comparative example and thus relatively weakened. As a result, in the semiconductor package 1000 of the present embodiment, a delamination phenomenon that the corner and/or edge portion of the first memory chip 200-1 is separated from the base chip BC may be prevented.

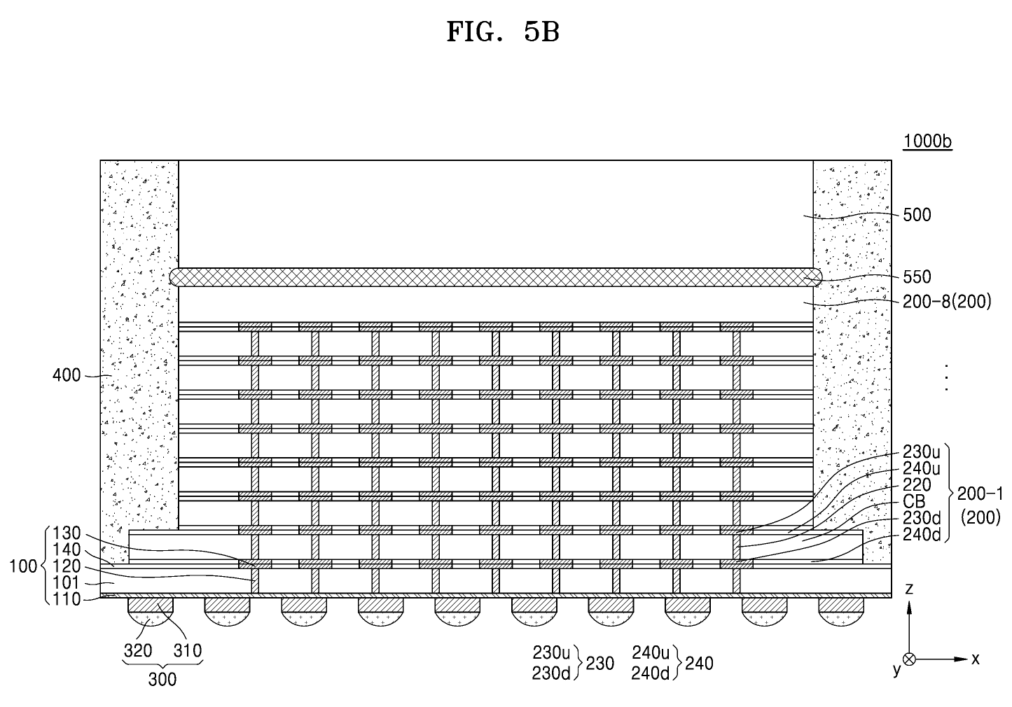

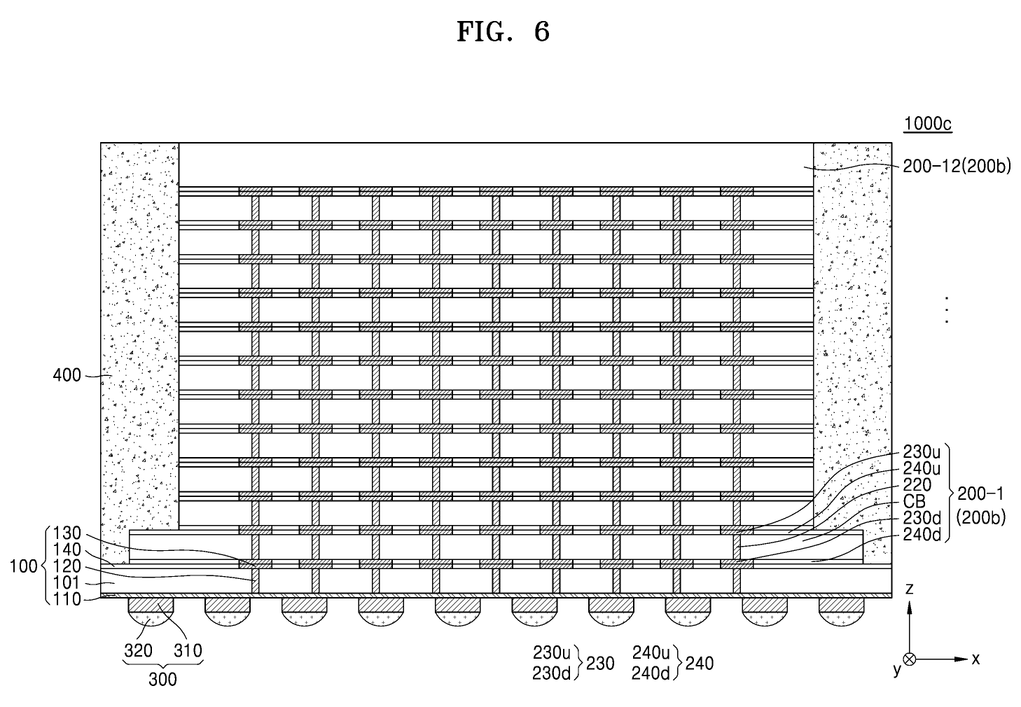

FIGS. 5A and 5B are cross-sectional views of semiconductor packages 1000a and 1000b according to embodiments. The description made with reference to FIGS. 1 to 4B may not be repeated, and may be briefly described or omitted for convenience of description.

Referring to FIG. 5A, the semiconductor package 1000a of the present embodiment may differ from the semiconductor package 1000 of FIG. 1 in the structure of memory chips 200a. For example, the semiconductor package 1000a of the present embodiment may include the base chip 100, the memory chips 200a, the external connection terminal 300, and the sealing material 400. The base chip 100, the external connection terminal 300, and the sealing material 400 may be the same as described with respect to those of the semiconductor package 1000 of FIG. 1.

In the memory chips 200a of the semiconductor package 1000a of the present embodiment, the horizontal sizes (e.g., widths/lengths) of the first memory chip 200-1 and a second memory chip 200a-2 may be greater than those of the other memory chips 200a. For example, the horizontal sizes (e.g., plan view areas) of the third to eighth memory chips 200-3 to 200-8 may be the same as each other, and the horizontal sizes (e.g., plan view areas) of the first and second memory chips 200-1 and 200a-2 may be smaller than that of the base chip 100 and larger than that of the third memory chip 200-3. The size relationship among the base chip 100, the first and second memory chips 200-1 and 200a-2, and the third memory chip 200-3 is the same as described with respect to that of the semiconductor package 1000 of FIG. 1.

In the semiconductor package 1000a of the present embodiment, the structure of the memory chips 200a is not limited to a structure in which the horizontal sizes of the first and second memory chips 200-1 and 200a-2 are larger than those of the other memory chips 200a. For example, in some embodiments, the structure of the memory chips 200a may have a structure in which a half or less number of lower memory chips 200a disposed at a lower portion among the memory chips 200a are larger than the other memory chips 200a. For example, when the number of memory chips 200a is 2n (n is an integer of 4 or more), the structure of the memory chips 200a may have a structure in which n-th and lower memory chips 200a disposed at a lower portion among the memory chips 200a are larger than the other memory chips 200a.

Referring to FIG. 5B, the semiconductor package 1000b of the present embodiment may differ from the semiconductor package 1000 of FIG. 1 in that the former further includes a top dummy chip 500. For example, the semiconductor package 1000b of the present embodiment may include the base chip 100, the memory chips 200, the external connection terminal 300, the sealing material 400, and the top dummy chip 500. The base chip 100, the memory chips 200, the external connection terminal 300, and the sealing material 400 may be the same as described with respect to those of the semiconductor package 1000 of FIG. 1. However, because the top dummy chip 500 is added, the sealing material 400 may have a structure of covering/contacting even the side surface of the top dummy chip 500.

In the semiconductor package 1000b of the present embodiment, the top dummy chip 500 may be stacked on the memory chips 200 through an adhesive layer 550. The top dummy chip 500 may be added to satisfy the height standard of the semiconductor package 1000b. For example, for an HBM package, a height, an area, and the like are defined in the Joint Electron Device Engineering Council Solid State Technology Association (JEDEC) standard, and when the semiconductor package 1000b of the present embodiment is an HBM package, the top dummy chip 500 having a proper height may be disposed on the memory chips 200 such that the height of the semiconductor package 1000b satisfies the JEDEC standard.

In the semiconductor package 1000b of the present embodiment, by adding the top dummy chip 500, the eighth or the uppermost memory chip 200-8 may have the same thickness as or a similar thickness to those of the other memory chips 200. However, the semiconductor package 1000b is not limited thereto, and in some embodiments, even when the top dummy chip 500 is included, the eighth or the uppermost memory chip 200-8 may be thicker than each of the other memory chips 200. However, when the total height of the semiconductor package 1000b is adjustable by adjusting the thickness of the eighth or the uppermost memory chip 200-8, the top dummy chip 500 may be omitted.

FIG. 6 is a cross-sectional view of a semiconductor package 1000c according to an embodiment. The description made with reference to FIGS. 1 to 5B may not be repeated, and may be briefly described or omitted for convenience of description.

Referring to FIG. 6, the semiconductor package 1000c of the present embodiment may differ from the semiconductor package 1000 of FIG. 1 in the structure of memory chips 200b. For example, the semiconductor package 1000c of the present embodiment may include the base chip 100, the memory chips 200b, the external connection terminal 300, and the sealing material 400. The base chip 100, the external connection terminal 300, and the sealing material 400 may be the same as described with respect to those of the semiconductor package 1000 of FIG. 1.

The semiconductor package 1000c of the present embodiment may include 12 memory chips 200b. For example, the 12 memory chips 200b, e.g., first to twelfth memory chips 200-1 to 200-12, may be stacked on the base chip 100. Because the semiconductor package 1000c includes the 12 memory chips 200b, the sealing material 400 may have a structure of covering/contacting even the side surface of the uppermost memory chip, i.e., the twelfth memory chip 200-12.

The twelfth/uppermost memory chip 200-12 may not include a through electrode. In addition, the upper surface of the twelfth/uppermost memory chip 200-12 may be exposed from the sealing material 400. However, in some embodiments, the upper surface of the twelfth/uppermost memory chip 200-12 may be covered by the sealing material 400. The thickness of the twelfth/uppermost memory chip 200-12 may be greater than those of the other memory chips 200b. However, in some embodiments, the twelfth/uppermost memory chip 200-12 may have the same or substantially the same thickness as each of the other memory chips 200b.

Even in the semiconductor package 1000c of the present embodiment, the first memory chip 200-1 may be larger than each of the other memory chips 200b, e.g., in a plan view. As described above, because the first memory chip 200-1 has a larger size (e.g., plan view areas) than the other memory chips 200b and disposed on and bonded to the upper surface of the base chip 100, a delamination phenomenon at a corner and/or an edge of the memory chips 200b, in particular, the first memory chip 200-1, may be effectively suppressed. In addition, as described with respect to the semiconductor package 1000a of FIG. 5A, even in the semiconductor package 1000c of the present embodiment, a plurality of memory chips 200b disposed at a lower portion, without being limited to the first memory chip 200-1, may be larger than the other memory chips 200b, e.g., in a plan view.

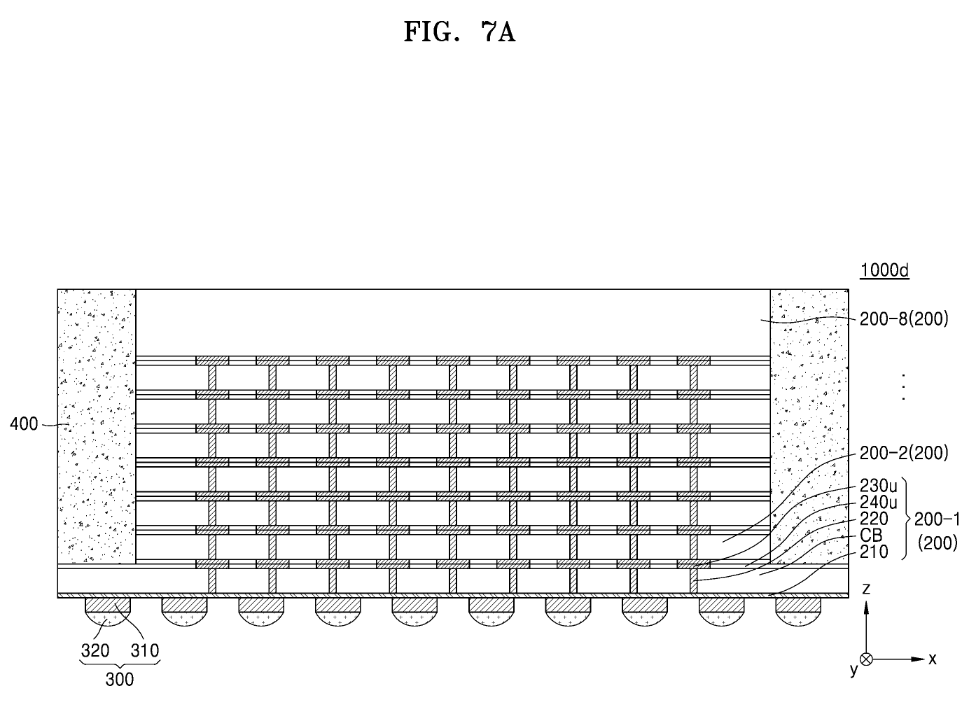

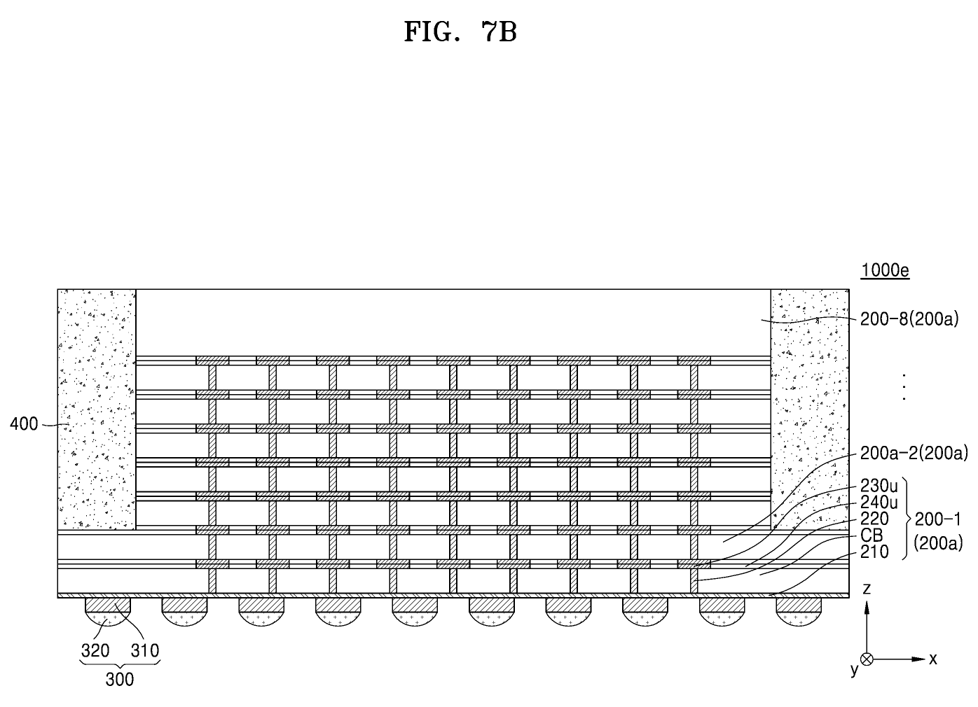

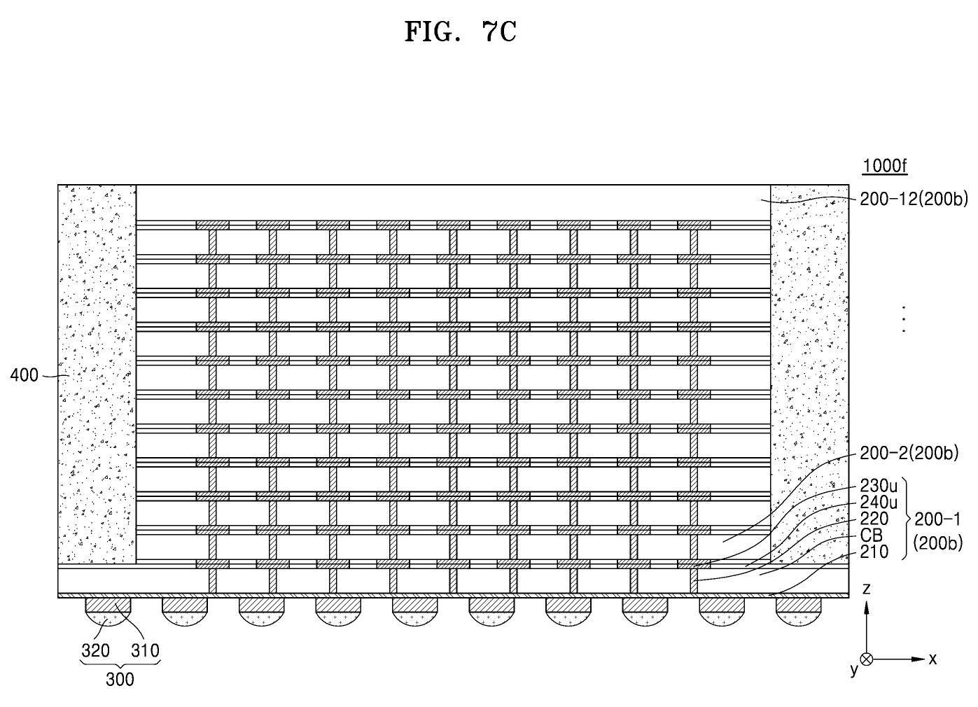

FIGS. 7A to 7C are cross-sectional views of semiconductor packages 1000d, 1000e, and 1000f according to embodiments. The description made with reference to FIGS. 1 to 6 may not be repeated, and may be briefly described or omitted for convenience of description.

Referring to FIG. 7A, the semiconductor package 1000d of the present embodiment may differ from the semiconductor package 1000 of FIG. 1 in that the former does not include a base chip. For example, the semiconductor package 1000d of the present embodiment may include the memory chips 200, the external connection terminal 300, and the sealing material 400. The memory chips 200, the external connection terminal 300, and the sealing material 400 may be the same as described with respect to those of the semiconductor package 1000 of FIG. 1.

Because the semiconductor package 1000d of the present embodiment does not include a base chip, the first memory chip 200-1 may function as a support substrate of the semiconductor package 1000d. In addition, the external connection terminal 300 may be disposed on the lower surface of the first memory chip 200-1. Therefore, the semiconductor package 1000d of the present embodiment may be used by being directly stacked on an interposer, a Si-bridge, or the like without a base chip. For example, devices functioning as a base chip may be included in the interposer, the Si-bridge, or the like, and in this case, the base chip may be omitted. Even in the semiconductor package 1000d of the present embodiment, like in the semiconductor package 1000 of FIG. 1, the horizontal size (e.g., the plan view area) of the first memory chip 200-1 may be larger than the horizontal sizes (e.g., the plan view areas) of the other memory chips 200.

As a reference, in the first memory chip 200-1 of FIG. 7A, only the upper pad 230u and the upper protective layer 240u are shown, and a lower pad and a lower protective layer are not shown. For example, in the present embodiment, the upper pad 330u and the upper protective layer 240u may be formed on an upper surface of the chip body layer CB of the first memory chip 200-1, but no lower pad and no lower protective layer may be formed on a bottom surface of the chip body layer CB of the first memory chip 200-1. In addition, similar to the base chip 100 of FIG. 1, an active layer 210 is illustrated in the first memory chip 200-1. The active layer 210 may include an integrated circuit layer and a multi-wiring layer. The first memory chip 200-1 of FIG. 7A may be the same as the first memory chips 200-1 of embodiments illustrated in FIGS. 7B and 7C.

Referring to FIG. 7B, the semiconductor package 1000e of the present embodiment may be similar to the semiconductor package 1000d of FIG. 7A in that a base chip is not included. However, similar to the semiconductor package 1000a of FIG. 5A, in the memory chips 200a of the semiconductor package 1000e of the present embodiment, the first and second memory chips 200-1 and 200a-2 may have a larger size than the other memory chips 200a. As described above, because the second memory chip 200a-2 has a larger size than the other memory chips 200a on the upper side/portion, a delamination phenomenon at a corner and/or an edge of the second memory chip 200a-2 may be prevented.

In some embodiments, the second memory chip 200a-2 may have a size smaller than that of the first memory chip 200-1 and larger than those of the other memory chips 200a. For example, the size relationship among the base chip 100, the first memory chip 200-1, and the second memory chip 200-2 in the semiconductor package 1000 of FIG. 1 may be applied to the size relationship among the first memory chip 200-1, the second memory chip 200a-2, and the third memory chip 200-3 in the semiconductor package 1000e of the present embodiment.

Referring to FIG. 7C, the semiconductor package 1000f of the present embodiment may be similar to the semiconductor package 1000d of FIG. 7A in that a base chip is not included. However, similarly to the semiconductor package 1000c of FIG. 6, the semiconductor package 1000f of the present embodiment may include 12 memory chips 200b. A structure without a base chip is the same as described with respect to that of the semiconductor package 1000d of FIG. 7A, and a structure including the 12 memory chips 200b is the same as described with respect to that of the semiconductor package 1000c of FIG. 6.

In some embodiments, the first and second memory chips 200-1 and 200-2 may have a larger size than the other memory chips 200b. In some embodiments, the second memory chip 200-2 may have a size smaller than that of the first memory chip 200-1 and larger than those of the other memory chips 200b. In some embodiments, a plurality of memory chips 200b disposed at a lower portion on the first memory chip 200-1 may have the same large size as the first memory chip 200-1 or have a size smaller than that of the first memory chip 200-1 and larger than those of the other memory chips 200b.

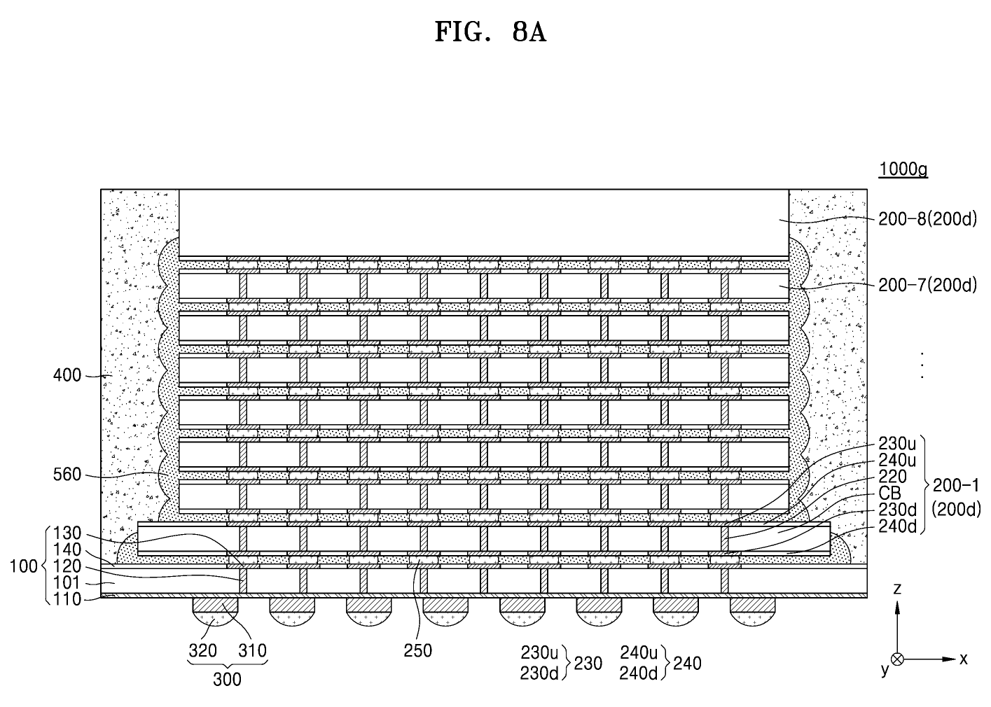

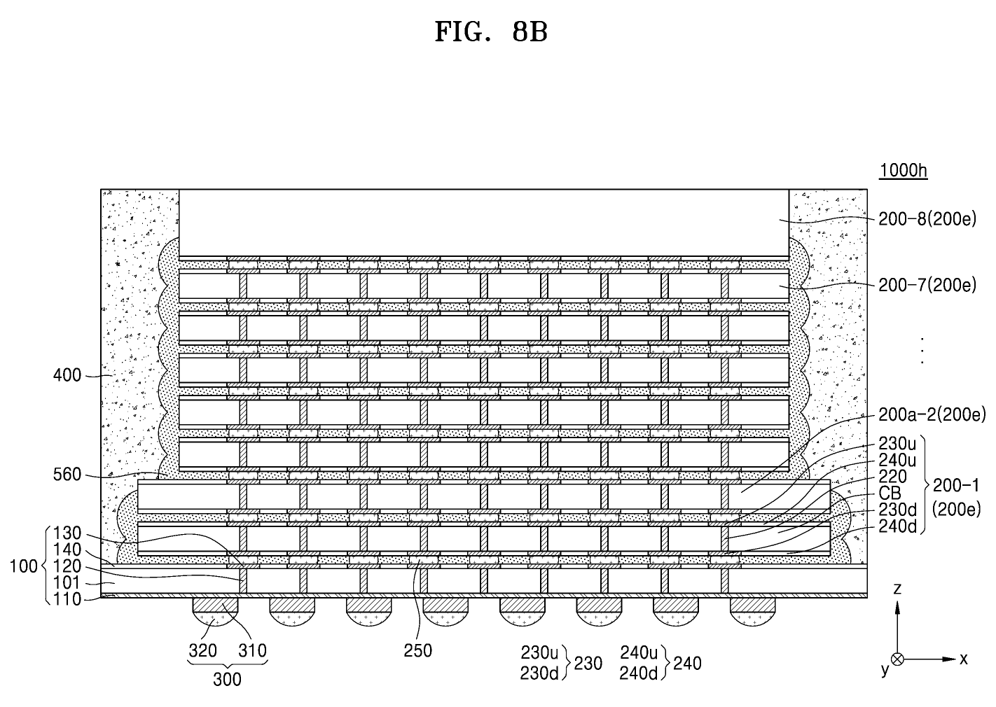

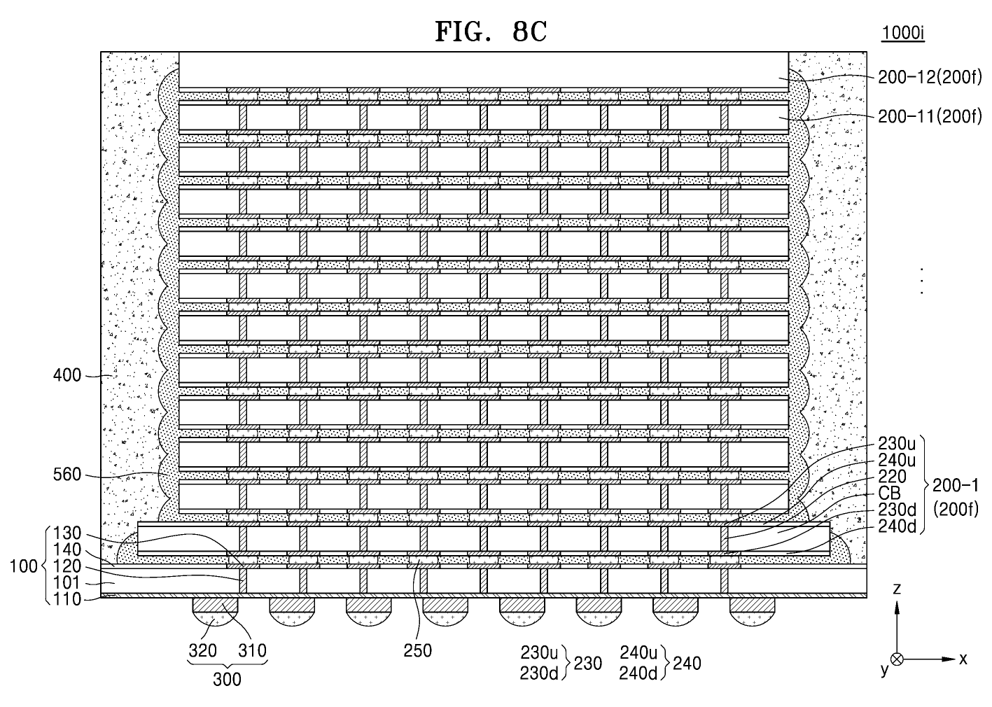

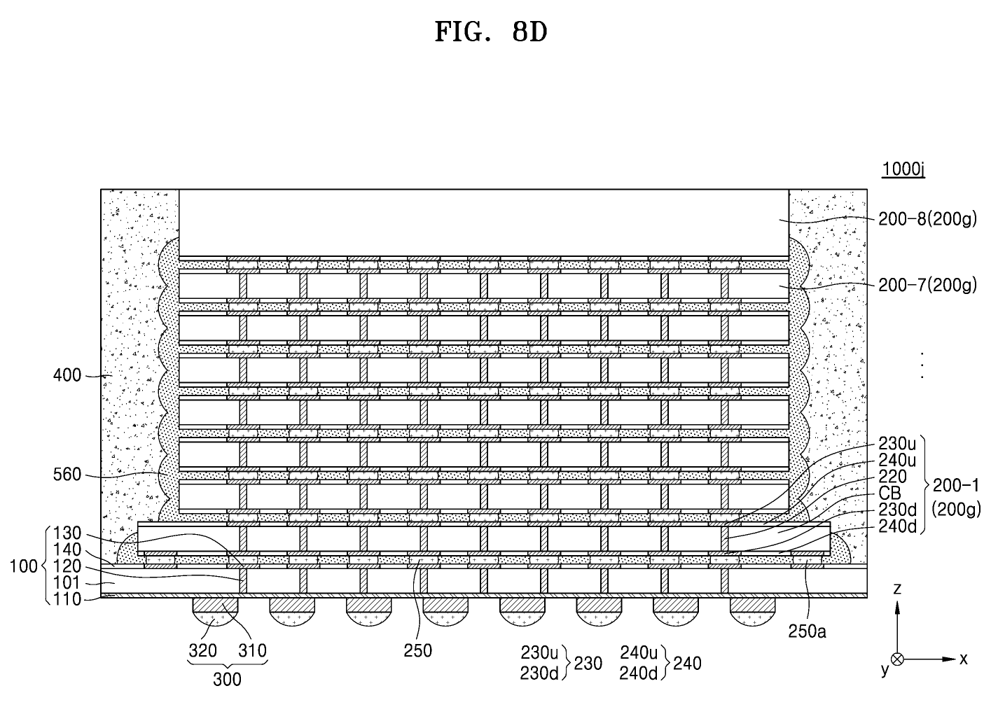

FIGS. 8A to 8D are cross-sectional views of semiconductor packages 1000g, 1000h, 1000i, and 1000j according to embodiments. The description made with reference to FIGS. 1 to 7C may not be repeated, and may be briefly described or omitted for convenience of description.

Referring to FIG. 8A, the semiconductor package 1000g of the present embodiment may completely differ from the semiconductor packages 1000 and 1000a to 1000f described above in the stacked structure of memory chips 200d. For example, the semiconductor package 1000g of the present embodiment may include the base chip 100, the memory chips 200d, the external connection terminal 300, and the sealing material 400. The base chip 100, the external connection terminal 300, and the sealing material 400 may be the same as described with respect to those of the semiconductor package 1000 of FIG. 1.

In the semiconductor package 1000g of the present embodiment, each of the memory chips 200d may be stacked on the base chip 100 or a lower memory chip 200d through a first connection terminal 250. For example, a first connection terminal 250 may be provided between the upper pad 130 of the base chip 100 and the lower pad 230d of the first memory chip 200-1. Regarding two adjacent memory chips 200d, a first connection terminal 250 may be provided between the upper pad 230u of a lower memory chip 200d and the lower pad 230d of an upper memory chip 200d.

The first connection terminal 250 may include, for example, a bump. The bump is the same as described with respect to the bump 320 of the external connection terminal 300 of the semiconductor package 1000 of FIG. 1. In some embodiments, the first connection terminal 250 may be a solder, a solder bump, or the like. The first connection terminal 250 may further include a pillar, and the bump may be disposed on the pillar. The pillar is the same as described with respect to the pillar 310 of the external connection terminal 300 of the semiconductor package 1000 of FIG. 1. In some embodiments, the pillar may function as a chip pad, and in this case, a chip pad, i.e., the lower pad 230d, may not be formed on the lower surface of a memory chip 200d.

In the semiconductor package 1000g of the present embodiment, because the memory chips 200d are stacked through the first connection terminals 250, adhesive layers 560 may be provided between the base chip 100 and the first connection terminal 250 and between two adjacent memory chips 200d. For example, the adhesive layers 560 may fill between the base chip 100 and the first memory chip 200-1 and between adjacent memory chips 200d and cover/contact the side surfaces of first connection terminals 250. In addition, as shown in FIG. 8A, the adhesive layers 560 may protrude from and cover/contact the side surfaces of the memory chips 200d. In some embodiments, the adhesive layers 560 may protrude from the side surfaces of the memory chips 200d but cover/contact only a portion of the side surface of each of the memory chips 200d. In this case, on the side surface of each of the memory chips 200d, a lower-side adhesive layer 560 may be separated from an upper-side adhesive layer 560 without adhering to each other.

The adhesive layer 560 may include, for example, a non-conductive film (NCF). The NCF may be used as, for example, an adhesive layer when semiconductor chips are bonded to each other by TCB in a semiconductor chip stacking process. However, the material of the adhesive layer 560 is not limited to the NCF.

Even in the semiconductor package 1000g of the present embodiment, like in the semiconductor package 1000 of FIG. 1, the horizontal size of the first memory chip 200-1 may be larger than the horizontal sizes of the other memory chips 200. For example, the size relationship among the base chip 100, the first memory chip 200-1, and the second memory chip 200-2 may be the same as or similar to the size relationship among the base chip 100, the first memory chip 200-1, and the second memory chip 200-2 in the semiconductor package 1000 of FIG. 1.

Referring to FIG. 8B, the semiconductor package 1000h of the present embodiment may differ from the semiconductor package 1000g of FIG. 8A in the stacked structure of memory chips 200e. For example, the semiconductor package 1000h of the present embodiment may include the base chip 100, the memory chips 200e, the external connection terminal 300, and the sealing material 400. The base chip 100, the external connection terminal 300, and the sealing material 400 may be the same as described with respect to those of the semiconductor package 1000 of FIG. 1.

In the memory chips 200e of the semiconductor package 1000h of the present embodiment, the horizontal sizes/widths of the first and second memory chips 200-1 and 200a-2 may be larger than the horizontal sizes/widths of the other memory chips 200e. A structure in which the second memory chip 200a-2 has a larger size/width than the other memory chips 200e on the upper side or an upper portion of the semiconductor package 1000h is the same as described with respect to that of the semiconductor package 1000a of FIG. 5A. In addition, as described with respect to the semiconductor package 1000a of FIG. 5A, in some embodiments, without being limited to the first and second memory chips 200-1 and 200a-2, a plurality of memory chips 200e disposed at a lower portion may have a larger size than the other memory chips 200e.

Referring to FIG. 8C, the semiconductor package 1000i of the present embodiment may differ from the semiconductor package 1000g of FIG. 8A in the stacked structure of memory chips 200f. For example, the semiconductor package 1000i of the present embodiment may include the base chip 100, the memory chips 200f, the external connection terminal 300, and the sealing material 400. The base chip 100, the external connection terminal 300, and the sealing material 400 may be the same as described with respect to those of the semiconductor package 1000 of FIG. 1.

The semiconductor package 1000i of the present embodiment may include 12 memory chips 200f. Each of the 12 memory chips 200f may be stacked on the base chip 100 or an immediately lower memory chip 200f through the first connection terminal 250. The first connection terminal 250 is the same as described with respect to that of the semiconductor package 1000g of FIG. 8A. In addition, a structure including the 12 memory chips 200f is the same as described with respect to that of the semiconductor package 1000c of FIG. 6. In some embodiments, the first and second memory chips 200-1 and 200-2 may have a larger size than the other memory chips 200f. In some embodiments, a plurality of memory chips 200f disposed at a lower portion may have a larger size than the other memory chips 200f.

Referring to FIG. 8D, the semiconductor package 1000j of the present embodiment may differ from the semiconductor package 1000g of FIG. 8A in the stacked structure of memory chips 200g. For example, the semiconductor package 1000j of the present embodiment may include the base chip 100, the memory chips 200g, the external connection terminal 300, and the sealing material 400. The base chip 100, the external connection terminal 300, and the sealing material 400 may be the same as described with respect to those of the semiconductor package 1000 of FIG. 1.

In the semiconductor package 1000j of the present embodiment, the first memory chip 200-1 among the memory chips 200g may be stacked on the base chip 100 through the first connection terminal 250 and a dummy connection terminal 250a. As shown in FIG. 8D, the dummy connection terminal 250a may be provided at an outer portion of the first memory chip 200-1. For example, the dummy connection terminal 250a may be provided at the outer portion of the first memory chip 200-1 protruding from the side surfaces of the other memory chips 200g, e.g., in a horizontal direction. As described above, because the dummy connection terminal 250a is provided to the outer portion of the first memory chip 200-1, a delamination phenomenon at a corner and/or an edge of the memory chips 200g, in particular, the first memory chip 200-1, may be effectively prevented. In addition, in some embodiments, the first and second memory chips 200-1 and 200-2 may have a larger size than the other memory chips 200g, or a plurality of memory chips 200g disposed at a lower portion may have a larger size than the other memory chips 200g, and in this case, the dummy connection terminal 250a may be provided to protruding/edge portions of the memory chips 200g having the larger size.

FIGS. 9A and 9B are respectively a perspective view and a cross-sectional view of a system package 2000 according to embodiments, wherein FIG. 9B is a cross-sectional view taken along line I-I' of FIG. 9A. Below description will be made with reference to FIG. 1 together with FIGS. 9A and 9B, and the above description made with reference to FIGS. 1 to 8D may not be repeated, and may be briefly described or omitted for brevity.

Referring to FIGS. 9A and 9B, the system package 2000 of the present embodiment may include semiconductor packages 1000, a package substrate 1100, an interposer 1200, a semiconductor device 1300, and an external sealing material 1500.

As shown in FIG. 9A, the semiconductor packages 1000 may include first to fourth semiconductor packages 1000-1 to 1000-4. For example, the semiconductor packages 1000 may be disposed two at each of opposite sides of the semiconductor device 1300 on the interposer 1200 through the external connection terminals 300. However, in the system package 2000 of the present embodiment, the number of semiconductor packages 1000 is not limited to 4. For example, one to three, or five or more semiconductor packages 1000 may be disposed on the interposer 1200.

Each of the semiconductor packages 1000 may be, for example, the semiconductor package 1000 of FIG. 1. Accordingly, the semiconductor package 1000 may include the base chip 100, the memory chips 200, the external connection terminal 300, and the sealing material 400. In addition, the first memory chip 200-1 among the memory chips 200 may have a larger horizontal size than the other memory chips 200. In FIG. 9B, the semiconductor package 1000 is simply/briefly represented/illustrated, and accordingly, connection pads and protective layers are not shown for convenience.

In the system package 2000 of the present embodiment, the semiconductor package 1000 may be an HBM package. Accordingly, the base chip 100 of the semiconductor package 1000 may be a buffer chip, and each of the memory chips 200 may be a DRAM chip. However, the semiconductor package 1000 is not limited to the HBM package. In addition, the semiconductor package 1000 is not limited to the semiconductor package 1000 of FIG. 1. For example, instead of the semiconductor package 1000 of FIG. 1, the semiconductor packages 1000a to 1000j of FIGS. 5A to 8D may be applied to the system package 2000.

The package substrate 1100 may be a support substrate, and the interposer 1200, the semiconductor packages 1000, the semiconductor device 1300, and the like may be stacked on the package substrate 1100. The package substrate 1100 may include at least one layer of wiring line therein. When a multi-layer wiring line is formed, wiring lines of different layers may be electrically connected to each other through vertical vias. The package substrate 1100 may be formed based on or may be, for example, a ceramic substrate, a printed circuit board (PCB), an organic substrate, an interposer substrate, or the like. A second external connection terminal 1150 may be disposed on the lower surface of the package substrate 1100. The system package 2000 may be stacked on an external system substrate, a main board, or the like through the second external connection terminal 1150.

The interposer 1200 may include an interposer substrate 1201, a wiring layer 1210, a through electrode 1220, and a second connection terminal 1250. The semiconductor packages 1000 and the semiconductor device 1300 may be mounted above the package substrate 1100 with the interposer 1200 therebetween. The interposer 1200 may electrically connect the semiconductor packages 1000 to the semiconductor device 1300. In addition, the interposer 1200 may electrically connect the semiconductor packages 1000 and the semiconductor device 1300 to the package substrate 1100.

The interposer substrate 1201 may include, for example, Si. Accordingly, the interposer 1200 may be a Si-interposer. The through electrode 1220 may extend lengthwise in a vertical direction by passing through the interposer substrate 1201 in the vertical direction. When the interposer substrate 1201 includes Si, the through electrode 1220 may be a TSV. The through electrode 1220 may extend to the wiring layer 1210 and be electrically connected to and/or contact wiring lines of the wiring layer 1210. According to an embodiment, the interposer 1200 may include only one wiring layer therein and not include a through electrode. The wiring layer 1210 may be disposed on the upper surface or the lower surface of the interposer substrate 1201. For example, the position relationship between the wiring layer 1210 and the through electrode 1220 may be relative. A pad on the upper surface of the interposer 1200 may be electrically connected to the through electrode 1220 via the wiring layer 1210.

The second connection terminal 1250 may be disposed on the lower surface of the interposer 1200 and electrically connected to the through electrode 1220. The interposer 1200 may be stacked on the package substrate 1100 through second connection terminals 1250. The second connection terminals 1250 may be electrically connected to the pad on the upper surface of the interposer 1200 via the through electrode 1220 and the wiring lines of the wiring layer 1210.

In the system package 2000 of the present embodiment, the interposer 1200 may be used to convert or transmit an electrical signal between the semiconductor packages 1000 and the semiconductor device 1300. Accordingly, the interposer 1200 may not include devices, such as active devices and passive devices. However, in some embodiments, the interposer 1200 may include devices configured to control signal transmission. An under-fill 1260 may fill between the interposer 1200 and the package substrate 1100 and between second connection terminals 1250. In some embodiments, the under-fill 1260 may be replaced with an adhesive layer or an adhesive film.

The semiconductor device 1300 may be stacked on a center portion of the interposer 1200 through third connection terminals 1350. The semiconductor device 1300 may have a chip or package structure. For example, the semiconductor device 1300 may be a semiconductor chip or a semiconductor package. In the system package 2000 of the present embodiment, the semiconductor device 1300 may have a chip structure. For example, the semiconductor device 1300 may include a logic chip. The semiconductor device 1300 may include a plurality of logic devices therein. The plurality of logic devices may include, for example, AND, NAND, OR, NOR, XOR, XNOR, INV, ADD, DLY, FIL, MXT/MXIT, OAI, AO, AOI, D flip-flop, reset flip-flop, master-slaver flip-flop, latch, counter, and buffer devices. The plurality of logic devices may perform various types of signal processing, such as analog signal processing, A/D conversion, and control. The semiconductor device 1300 may be a central processing unit (CPU) chip, a system on glass (SOG) chip, a micro-processor unit (MPU) chip, a graphics processing unit (GPU) chip, a neural processing unit (NPU) chip, an application processor (AP) chip, a control chip, or the like according to the function thereof.

In the system package 2000 of the present embodiment, the semiconductor device 1300 may have a chip structure, wherein the chip structure may be a system on chip (SoC) structure or a chiplet structure. The SoC structure may have a structure in which a plurality of systems are integrated in a single chip. Accordingly, the semiconductor device 1300 of the SoC structure may perform computation function, data storage, analog and digital signal conversion, and the like in a single chip. The chiplet structure may have a structure in which a logic chip is divided into separate chips according to the functions thereof and the chips are electrically connected to each other. The semiconductor device 1300 of the chiplet structure may overcome performance limitation which a single chip has.

The external sealing material 1500 may cover and seal the semiconductor device 1300 and the semiconductor packages 1000 on the interposer 1200. As shown in FIG. 9B, the external sealing material 1500 may not cover the upper surfaces of the semiconductor device 1300 and the semiconductor packages 1000. However, in some embodiments, the external sealing material 1500 may cover the upper surface of at least one of the semiconductor device 1300 and the semiconductor packages 1000. Although not shown in FIGS. 9A and 9B, the system package 2000 of the present embodiment may further include a second external sealing material covering and sealing the interposer 1200 and the external sealing material 1500 on the package substrate 1100.

As an example, the structure of the system package 2000 of the present embodiment may be a 2.5-dimensional (2.5D) package structure, and the 2.5D package structure may be a relative concept with respect to a three-dimensional (3D) package structure in which all semiconductor chips are stacked without an interposer. Both the 2.5D package structure and the 3D package structure may be included in a system in package (SIP) structure. In addition, the system package 2000 of the present embodiment may be a semiconductor package but is named as a system package to be terminologically distinguished from the semiconductor package 1000 that is a component of the system package 2000.

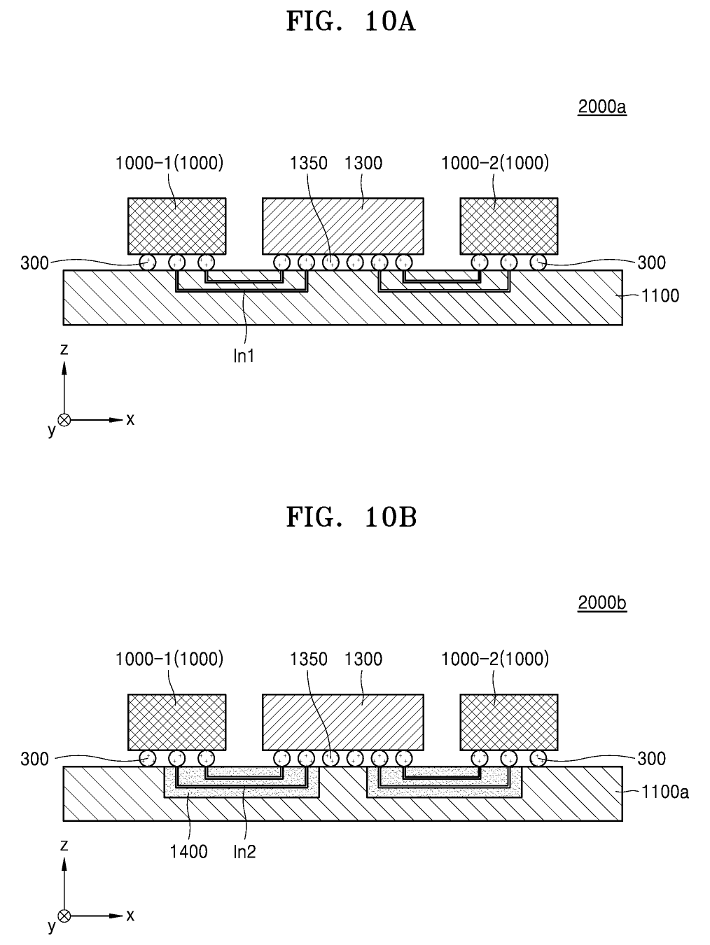

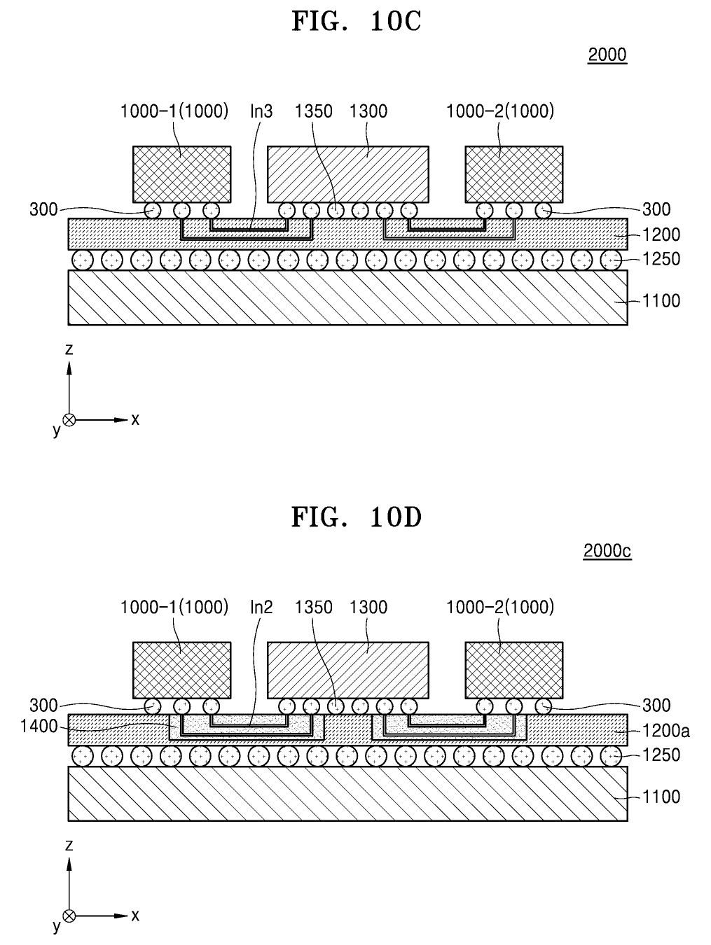

FIGS. 10A to 10D are cross-sectional views of semiconductor packages 2000a, 2000b, 2000, and 2000c according to embodiments. The description made with reference to FIGS. 1 to 9B may not be repeated, and may be briefly described or omitted for convenience of description. FIGS. 10A to 10D are cross-sectional views corresponding to FIG. 9B, schematically show only the semiconductor packages 1000, a mounting substrate (the package substrate 1100 or the interposer 1200), and the semiconductor device 1300 in view of an electrical connection structure between the semiconductor packages 1000 and the semiconductor device 1300, and do not show a second external connection terminal and an external sealing material.

Referring to FIG. 10A, the system package 2000a of the present embodiment may include the semiconductor packages 1000, the package substrate 1100, and the semiconductor device 1300. Compared to the system package 2000 of FIG. 9B, the system package 2000a of the present embodiment may not include an interposer. Accordingly, the semiconductor packages 1000 may be mounted on the package substrate 1100 through the external connection terminals 300. In addition, the semiconductor device 1300 may be mounted on the package substrate 1100 through the third connection terminals 1350. The particular structures, functions, and the like of the package substrate 1100, the semiconductor packages 1000, and the semiconductor device 1300 are the same as described with respect to those of the system package 2000 of FIG. 9B. As shown in FIG. 10A, in the system package 2000a of the present embodiment, the semiconductor packages 1000 may be electrically connected to the semiconductor device 1300 via a first connection wiring In1 of the package substrate 1100. The first connection wiring In1 may be a part of the wiring lines of the package substrate 1100.

Referring to FIG. 10B, the system package 2000b of the present embodiment may include the semiconductor packages 1000, a package substrate 1100a, the semiconductor device 1300, and Si-bridges 1400. Compared to the system package 2000a of FIG. 10A, the system package 2000b of the present embodiment may further include the Si-bridges 1400.

The Si-bridges 1400 may be provided inside the package substrate 1100a, as shown in FIG. 10B. The Si-bridges 1400 may be provided inside the package substrate 1100a at corresponding positions between the semiconductor packages 1000 and the semiconductor device 1300. In addition, each of the Si-bridges 1400 may vertically overlap a portion of each of the semiconductor packages 1000 and a portion of the semiconductor device 1300. In the system package 2000b of the present embodiment, the semiconductor packages 1000 may be provided at both sides of the semiconductor device 1300 in the X direction. Therefore, the Si-bridges 1400 may be provided at both sides of the semiconductor device 1300 in the X direction (e.g., a horizontal direction).

Each of the Si-bridges 1400 may include a second connection wiring In2 therein. The Si-bridges 1400 may electrically connect the semiconductor packages 1000 to the semiconductor device 1300 via the second connection wirings In2. As a result, in the system package 2000b of the present embodiment, the semiconductor packages 1000 may be electrically connected to the semiconductor device 1300 by using the Si-bridges 1400 separately/additionally provided inside the package substrate 1100a.

Referring to FIG. 10C, the system package 2000 of the present embodiment may be substantially the same as the system package 2000 of FIG. 9B. Accordingly, the system package 2000 of the present embodiment may include the semiconductor packages 1000, the package substrate 1100, the interposer 1200, and the semiconductor device 1300. The semiconductor packages 1000 may be mounted on the interposer 1200 through the external connection terminals 300, and the semiconductor device 1300 may be mounted on the interposer 1200 through the third connection terminals 1350. As shown in FIG. 10C, in the system package 2000 of the present embodiment, the semiconductor packages 1000 may be electrically connected to the semiconductor device 1300 via third connection wirings In3 of the interposer 1200. The third connection wiring In3 may include the wiring lines of the wiring layer 1210 and the through electrode 1220 or include only the wiring lines of the wiring layer 1210.

Referring to FIG. 10D, the system package 2000c of the present embodiment may include the semiconductor packages 1000, the package substrate 1100, an interposer 1200a, the semiconductor device 1300, and the Si-bridges 1400. Compared to the system package 2000 of FIG. 10C, the system package 2000c of the present embodiment may further include the Si-bridges 1400.

The Si-bridges 1400 may be provided inside the interposer 1200a, as shown in FIG. 10D. The Si-bridges 1400 may be provided inside the interposer 1200a at corresponding positions between the semiconductor packages 1000 and the semiconductor device 1300. In addition, each of the Si-bridges 1400 may vertically overlap a portion of each of the semiconductor packages 1000 and a portion of the semiconductor device 1300. In the system package 2000c of the present embodiment, the semiconductor packages 1000 may be provided at both sides of the semiconductor device 1300 in the X direction. Therefore, the Si-bridges 1400 may be provided at both sides of the semiconductor device 1300 in the X direction.

Each of the Si-bridge 1400 may include the second connection wiring In2 therein. The Si-bridges 1400 may electrically connect the semiconductor packages 1000 to the semiconductor device 1300 via the second connection wirings In2. As a result, in the system package 2000c of the present embodiment, the semiconductor packages 1000 may be electrically connected to the semiconductor device 1300 by using the Si-bridges 1400 separately/additionally provided inside the interposer 1200a.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. A semiconductor package comprising:
a base chip;
a plurality of memory chips disposed on the base chip; and
a sealing material sealing the plurality of memory chips on the base chip,
wherein each of the plurality of memory chips is disposed on a center portion of an upper surface of the base chip,
the plurality of memory chips comprise at least one first memory chip at a bottom thereof and at least one second memory chip disposed on the at least one first memory chip,
each of the at least one first memory chip has a larger plan view area than each of the at least one second memory chip,
a first side surface of the base chip, a second side surface of the at least one first memory chip, and a third side surface of the at least one second memory chip extend parallel to each other in a first horizontal direction, and
in a second horizontal direction perpendicular to the first horizontal direction, a first gap between the first side surface and the third side surface is greater than a second gap between the second side surface and the third side surface.

2. The semiconductor package of claim 1, wherein the second gap is greater than half of the first gap.

3. The semiconductor package of claim 1, wherein each of the plurality of memory chips is stacked on the base chip or an immediately lower memory chip through hybrid copper bonding (HCB).

4. The semiconductor package of claim 1, wherein each of the plurality of memory chips is stacked on the base chip or an immediately lower memory chip through a connection terminal.

5. The semiconductor package of claim 1, wherein,
among the plurality of memory chips, only one memory chip that is a lowermost memory chip is the first memory chip, and the remaining memory chips are the at least one second memory chip.

6. The semiconductor package of claim 1, wherein
the number of memory chips is 2n (n is an integer of 4 or more),
first to n^{th} or less than the n^{th} memory chips from a bottom among the plurality of memory chips are the at least one first memory chip, and the remaining memory chips are the at least one second memory chip.

7. The semiconductor package of claim 1, further comprising a dummy chip disposed on the plurality of memory chips.

8. The semiconductor package of claim 1, wherein a side surface of the sealing material is coplanar with the first side surface of the base chip.

9. The semiconductor package of claim 8, wherein,
among the plurality of memory chips, an uppermost memory chip is thicker than the other memory chips, and
an upper surface of the sealing material is coplanar with an upper surface of the uppermost memory chip.

10. The semiconductor package of claim 8, further comprising
a dummy chip disposed on the plurality of memory chips,
wherein an upper surface of the sealing material is coplanar with an upper surface of the dummy chip.

11. The semiconductor package of claim 1, wherein
each of the plurality of memory chips is a dynamic random access memory (DRAM) chip, and
the semiconductor package is a high bandwidth memory (HBM) package.

12. A semiconductor package comprising:
at least one first memory chip; and
at least one second memory chip disposed on the at least one first memory chip,
wherein each of the at least one first memory chip and the at least one second memory chip is stacked through hyper copper bonding (HCB) on a first memory chip or a second memory chip disposed immediately therebelow,
each of the at least one first memory chip has a larger plan view area than each of the at least one second memory chip,
the at least one second memory chip is disposed on a center portion of an upper surface of the at least one first memory chip,
a first side surface of the at least one first memory chip and a second side surface of the at least one second memory chip extend parallel to each other in a first horizontal direction, and
the first side surface and the second side surface have a first gap in a second horizontal direction perpendicular to the first horizontal direction.

13. The semiconductor package of claim 12, further comprising
a base chip disposed beneath the at least one first memory chip,
wherein the at least one first memory chip is disposed on a center portion of an upper surface of the base chip,
a third side surface of the base chip extends in the first horizontal direction, parallel to the first side surface of the at least one first memory chip,
the second side surface and the third side surface have a second gap in the second horizontal direction, and the second gap is greater than the first gap.

14. The semiconductor package of claim 13, further comprising
a sealing material sealing the at least one first memory chip and the at least one second memory chip, on the base chip,
wherein a side surface of the sealing material is coplanar with the third side surface of the base chip, and
an upper surface of the sealing material is coplanar with an upper surface of an uppermost second memory chip.

15. The semiconductor package of claim 13, further comprising:
a dummy chip disposed on the at least one second memory chip; and
a sealing material sealing the at least one first memory chip, the at least one second memory chip and the dummy chip, on the base chip,
wherein a side surface of the sealing material is coplanar with the third side surface of the base chip, and
an upper surface of the sealing material is coplanar with an upper surface of the dummy chip.

16. A semiconductor package comprising:
a package substrate;
a first semiconductor device on the package substrate; and
at least one second semiconductor device on the package substrate and adjacent to the first semiconductor device,
wherein each of the at least one second semiconductor device
has a package structure including a base chip, a plurality of memory chips disposed on the base chip, and a sealing material sealing the plurality of memory chips on the base chip,
the plurality of memory chips comprise at least one first memory chip at a bottom thereof and at least one second memory chip disposed on the at least one first memory chip,
each of the at least one first memory chip has a larger plan view area than each of the at least one second memory chip,
a first side surface of the base chip, a second side surface of the at least one first memory chip, and a third side surface of the at least one second memory chip extend parallel to each other in a first horizontal direction, and
in a second horizontal direction perpendicular to the first horizontal direction, a first gap between the first side surface and the third side surface is greater than a second gap between the second side surface and the third side surface.

17. The semiconductor package of claim 16, wherein
each of the plurality of memory chips is stacked on the base chip or an immediately lower memory chip among the plurality of memory chips through hybrid copper bonding (HCB) or a connection terminal.

18. The semiconductor package of claim 16, wherein
the first semiconductor device comprises a logic chip, and
the at least one second semiconductor device comprises a high bandwidth memory (HBM) package.

19. The semiconductor package of claim 16, further comprising
an intermediate substrate disposed on the package substrate,
wherein the first semiconductor device and the at least one second semiconductor device are disposed on the intermediate substrate and electrically connected to each other via the intermediate substrate.

20. The semiconductor package of claim 16, further comprising:
an intermediate substrate disposed on the package substrate; and
a silicon (Si)-bridge formed inside the intermediate substrate or inside the package substrate,
wherein the first semiconductor device is electrically connected to the at least one second semiconductor device via the Si-bridge.
